(19) United States
(12) Patent Application Publication
(10) Pub. No.: US 2017/0139638 A1
(43) Pub. Date: May 18, 2017

(54) MEMORY SYSTEM AND OPERATING METHOD THEREOF

(71) Applicant: SK hynix Inc., Gyeonggi-do (KR)

(72) Inventor: Jeen PARK, Gyeonggi-do (KR)

(21) Appl. No.: 15/096,744

(22) Filed: Apr. 12, 2016

(30) Foreign Application Priority Data
Nov. 13, 2015 (KR) 10-2015-0159811

(51) Int. Cl. G06F 3/06; G11C 11/56

(52) U.S. Cl. CPC G06F 3/0647; G06F 3/0611; G06F 3/0656; G06F 3/0659; G06F 3/0683; G11C 11/5642; G11C 11/5628; G06F 3/0688

(57) ABSTRACT

This technology relates to a memory system supporting a one-shot program and an operating method of the memory system The memory system may include: a first memory device comprising a first multi-level cell and a first multi-level buffer, a second memory device comprising a second multi-level cell and a second multi-level buffer, and a controller suitable for buffering input data in the first and the second multi-level buffers in an interleaving way, for rearranging and storing the buffered input data in a multi-level buffer selected from the first and second multi-level buffers if the input data have a size smaller than or equal to a preset size, wherein a one-shot program is performed on a memory device including the selected multi-level buffer.

### CROSS-REFERENCE TO RELATED APPLICATIONS

The present application claims priority of Korean Patent Application No, 10-2015-0159811, filed on Nov. 13, 2015, which is incorporated herein by reference in its entirety.

### BACKGROUND

1. Field

Exemplary embodiments of the present invention relate generally to a semiconductor design technology, and more particularly, to a memory system supporting a one-shot program and an operating method of the memory system.

2. Description of the Related Art

The computer environment paradigm has shifted to ubiquitous computing systems that can be used anywhere and at any time resulting in a rapidly increasing use of portable electronic devices such as mobile phones, digital cameras, and notebook computers continues to increase rapidly. These portable electronic devices generally use a memory system having a semiconductor memory device (also referred to hereinafter simply as a memory device) for storing data, that is, as a data storage device. A data storage device is used as main or auxiliary memory device of a portable electronic device.

Data storage devices using memory devices provide excellent stability, durability, high information access speed, and low power consumption, since they have no moving parts. Examples of data storage devices having such advantages include universal serial bus (USB) memory devices, memory cards having various interfaces, solid state drives (SSD) and so forth.

### SUMMARY

Various embodiments of the invention are directed to a memory system capable of an effective one-shot program in a plurality of memory devices each including multi-level cells and multi-level buffers and an operating method of the memory system.

In an embodiment, a memory system may include: a first memory device comprising a first multi-level cell and a first multi-level buffer, a second memory device comprising a second multi-level cell and a second multi-level buffer, and a controller suitable for buffering input data in the first and the second multi-level buffers in an interleaving way, for rearranging and storing the buffered input data in a multi-level buffer selected from the first and second multi-level buffers if the input data have a size smaller than or equal to a preset size, wherein a one-shot program is performed on a memory device including the selected multi-level buffer.

The controller may perform the one-shot program on each of the first and the second memory devices so that the data buffered in the first and the second multi-level buffers can be programmed into the first and the second memo devices if the input data have a size greater than the preset size.

The preset size may include a size of the input data corresponding to a size required for buffering the input data in each of the first and the second multi-level buffers at unit level.

Each of the first and the second multi-level buffers may include a plurality of lower level buffers and a plurality of higher level buffers, and if all of the input data have been buffered at the time of sequentially buffering the input data in the lower level buffers of the first and the second multi-level buffers, the controller may move the data buffered in the lower level buffers of the second multi-level buffer to the higher level buffers of the first multi-level buffer to perform the one-shot program on the first memory device.

If all of the input data have not been buffered at the time of completion of sequentially buffering the input data in the lower level buffers of the first and the second multi-level buffers, the controller may sequentially buffer the input data in the higher level buffers of the first and the second multi-level buffers based on the size of the input data which have not been buffered or may buffer the input data in the higher level buffers of the first multi-level buffer and buffers dummy data in the higher level buffers of the second multi-level buffer, to perform the one-shot program on each of the first and the second memory devices.

If all of the input data have been buffered at the time of buffering the input data in the lower level buffers of the first multi-level buffer, the controller may buffer the dummy data in the higher level buffers of the first multi-level buffer to perform the one-shot program on the first memory device.

The preset size may include a size of the input data corresponding to a half of a sum of sizes of the first and the second multi-level buffers.

Each of the first and second multi-level buffers may include a plurality of lower level buffers, a plurality of middle level buffers and a plurality of higher level buffers, and if all of the input data have been buffered at the time of completion of sequentially buffering the input data in the lower level buffers of the first and the second multi-level buffers and the middle level buffers of the first multi-level buffer, the controller may move data buffered in the middle level buffers of the first multi-level buffer to the higher level buffers of the first multi-level buffer and moves data buffered in the lower level buffers of the second multi-level buffer to the middle level buffers of the first multi-level buffer, to performs the one-shot program on the first memory device.

If all of the input data have not been buffered at the time of completion of sequentially buffering the input data in the lower level buffers of the first and the second multi-level buffers and the middle level buffers of the first multi-level buffer, the controller may sequentially buffer the input data in the middle level buffers of the second multi-level buffer and the higher level buffers of the first and the second multi-level buffers based on a size of the input data which have not been buffered or may sequentially buffer the input data in the middle level buffers of the second multi-level buffer and the higher level buffers of the first multi-level buffer, may buffer dummy data in the higher level buffers of the second multi-level buffer or may buffer the input data in the middle level buffers of the second multi-level buffer and buffers dummy data in the higher level buffers of the first and the second multi-level buffers to perform the one-shot program on each of the first and the second memory devices.

If all of the input data have been buffered at the time of completion sequentially buffering the input data in the lower level buffers of the first and the second multi-level buffers, the controller may move data buffered in the lower level buffers of the second multi-level buffer to the middle level buffers of the first multi-level buffer and buffers dummy data in the higher level buffers of the first multi-level buffer to perform the one-shot program on the first memory device.

If all of the input data have been buffered at the time of completion of buffering the input data in the lower level buffers of the first multi-level buffer, the controller may buffer the dummy data in the middle level buffers and the higher level buffers of the first multi-level buffer to perform the one-shot program on the first memory device.

In an embodiment, an operating method of a memory system comprising a first memory device comprising a first multi-level cell and a first multi-level buffer and a second memory device comprising a second multi-level cell and a second multi-level buffer, the operating method may include: a step of buffering input data in the first and the second multi-level buffers in an interleaving way and checking a size of the input data based on a preset size; a first program step of storing the buffered input data in a multi-level buffer selected from the first and the second multi-level buffers if, as a result of the checking, the input data have a size smaller than or equal to the preset size and performing a one-shot program on a memory device including the selected multi-level buffer; and a second program step of performing the one-shot program on each of the first and the second memory devices so that the data buffered in the first and the second multi-level buffers can be programmed into the first and the second memory devices if, as a result of the checking, the input data have a size greater than the preset size.

The preset size may include a size of the input data corresponding to a size required for buffering the input data in each of the first and the second multi-level buffers at unit level.

Each of the first and the second multi-level buffers may include a plurality of lower level buffers and a plurality of higher level buffers, and if, as a result of the checking, the input data having the preset size are found to have been sequentially buffered in the lower level buffers of the first and the second multi-level buffers, the first program step may include: moving data buffered in the lower level buffers of the second multi-level buffer to the higher level buffers of the first multi-level buffer, and performing the one-shot program on the first memory device.

If, as a result of the checking, the input data having the size smaller than the preset size are found to have been buffered in the lower level buffers of the first multi-level buffer, the first program step may include: buffering dummy data in the higher level buffers of the first multi-level buffer, and performing the one-shot program on the first memory device.

The second program step may include: performing the one-shot to program on each of the first and the second memory devices if, as a result of the checking, the input data having the size greater than the preset size are found to have been sequentially buffered in the lower level buffers and the higher level buffers of the first and the second multi-level buffers; and buffering the dummy data in the higher level buffers of the second multi-level buffer and performing the one-shot program on each of the first and the second memory devices if, as a result of the checking, the input data having the size greater than the preset size are found to have been sequentially buffered in the lower level buffers of the first and the second multi-level buffers and the higher level buffers of the first multi-level buffer.

The preset size may include a size of the input data corresponding to a half of a sum of sizes of the first and the second multi-level buffers.

Each of the first and second multi-level buffers may include a plurality of lower level buffers, a plurality of middle level buffers and a plurality of higher level buffers, and if, as a result of the checking, the input data having the preset size are found to have been sequentially buffered in the lower level buffers of the first and the second multi-level buffers and the middle level buffers of the first multi-level buffer, the first program step may include: moving data buffered in the middle level buffers of the first multi-level buffer to the higher level buffers of the first multi-level buffer, moving data buffered in the lower level buffers of the second multi-level buffer to the middle level buffers of the first multi-level buffer, and performing the one-shot program on the first memory device.

The first program step may include: moving data buffered in the lower level buffers of the second multi-level buffer to the middle level buffers of the first multi-level buffer, buffering dummy data in the higher level buffers of the first multi-level buffer, and performing the one-shot program on the first memory device if, as a result of the checking, the input data having the size smaller than the preset size are found to have been sequentially buffered in the lower level buffers of the first and the second multi-level buffers; and buffering dummy data in the middle level buffers and the higher level buffers of the first multi-level buffer and performing the one-shot program on the first memory device if, as a result of the checking, the input data having the size smaller than the preset size are found to have been buffered in the lower level buffers of the first multi-level buffer.

The second program step may include: performing the one-shot program on each of the first and the second memory devices if, as a result of the checking, the input data having the size greater than the preset size are found to have been sequentially buffered in the lower level buffers, the middle level buffers, and the higher level buffers of the first and the second multi-level buffers; buffering the dummy data in the higher level buffers of the second multi-level buffer and performing the one-shot program on each of the first and the second memory devices if, as a result of the checking, the input data having the size greater than the preset size are found to have been sequentially buffered in the lower level buffers and the middle level buffers of the first and the second multi-level buffers and the higher level buffers of the first multi-level buffer; and buffering the dummy data in the higher level buffers of the first and the second multi-level buffers and performing the one-shot program on the first and the second memory devices if, as a result of the checking, the input data having the size greater than the preset size are found to have been sequentially buffered in the lower level buffers and the middle level buffers of the first and the second multi-level buffers.

### BRIEF DESCRIPTION OF THE DRAWINGS

FIG. 1 is a diagram illustrating a data processing system including a memory system, according to an embodiment of the invention.

FIG. 2 is a diagram illustrating a memory device including a plurality of memory blocks, according to an embodiment of the invention.

FIG. 3 is a circuit diagram illustrating a memory block in a memory device, according to an embodiment of the invention.

FIGS. 4 to 11 are diagrams illustrating a memory device, according to various embodiments of the invention.

FIGS. 12A to 12E are block diagrams illustrating one-shot program operation performed by a memory system, according to a first embodiment of the invention.

FIGS. 13A to 13G are block diagrams illustrating one-shot program operation performed by a memory system, according to a second embodiment of the invention.

### DETAILED DESCRIPTION

Various embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete. Throughout the disclosure, like reference numerals refer to like parts throughout the various figures and embodiments of the present invention.

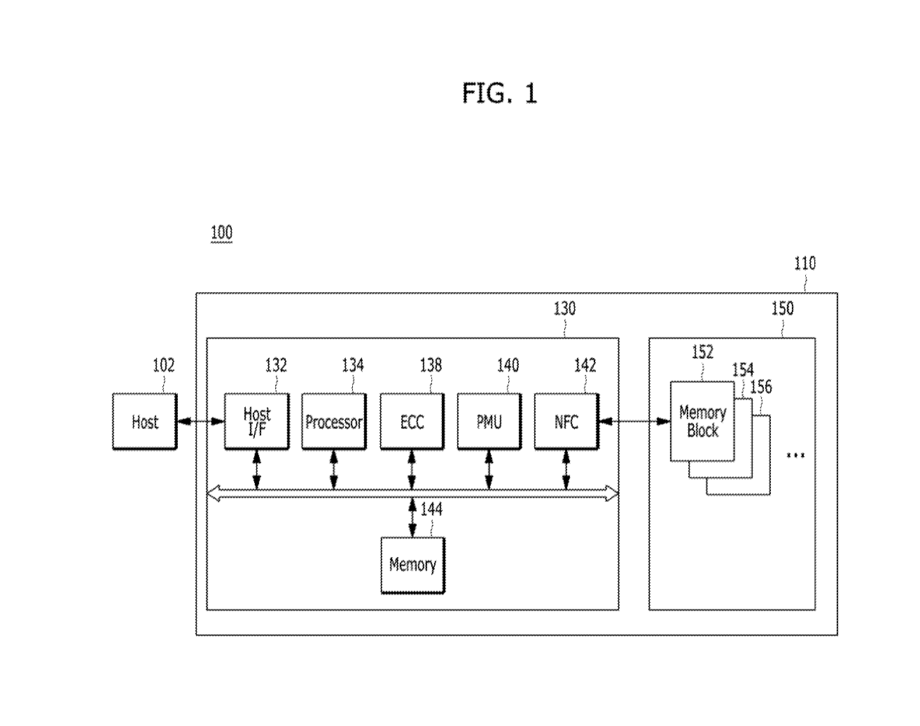

Referring now to FIG. 1, a data processing system 100 is provided, according to an embodiment of the present invention. The data processing system 100 may include a host 102 and a memory system 110.

The host 102 may include any suitable electronic device. For example, the host 102 may include a portable electronic device such as a mobile phone, an MP3 player, a laptop computer and the like. The host may include a non-portable electronic device such as a desktop computer, a game player, a TV, a projector and the like.

The memory system 110 may store data to be accessed by the to host 102 in response to a request from the host 102. The memory system 110 may be used as a main memory system or an auxiliary memory system of the host 102. The memory system 110 may be implemented to be coupled electrically with the host 102, according to a protocol of a host interface. One or more semiconductor memory devices may be used. Volatile or non-volatile memory devices may be used. For example, the memory system 110 may be implemented with a solid state drive (SSD), a multimedia card (MMC), an embedded MMC (eMMC), a reduced size MMC (RS-MMC) and a micro-MMC, a secure digital (SD) card, a mini-SD and a micro-SD a universal serial bus (USB) storage device, a universal flash storage (UFS) device, a compact flash (CF) card, a smart media (SM) card, a memory stick, and the like.

The storage devices for the memory system 110 may be implemented with a volatile memory device, such as a dynamic random access memory (DRAM), a static random access memory (SRAM) and the like. Alternatively, the storage devices for the memory system 110 may be implemented a nonvolatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), a resistive RAM (RRAM) and the like.

The memory system 110 may include a memory device 150 for storing data and a controller 130 for controlling storage of data in the to memory device 150. The stored data in the memory device 150 may be accessed by the host 102.

The controller 130 and the memory device 150 may be integrated into a single semiconductor device. For instance, the controller 130 and the memory device 150 may be integrated into a semiconductor device configured as a solid state drive (SSD). Configuring the memory system 110 as a SSD, may generally allow a significant increase in an operation speed of the host 102.

The controller 130 and the memory device 150 may be integrated into a semiconductor device configured as a memory card, such as a Personal Computer Memory Card International Association (PCMCIA) card, a compact flash (CF) card, a smart media (SM) card (SMC), a memory stick, a multimedia card (MMC), an RS-MMC and a micro-MMC, a secure digital (SD) card, a mini-SD, a micro-SD and an SDHC, a universal flash storage (UFS) device and the like.

Also, for example, the memory system 110 may be or comprise a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, an RFID device, one of various component elements configuring a computing system and the like.

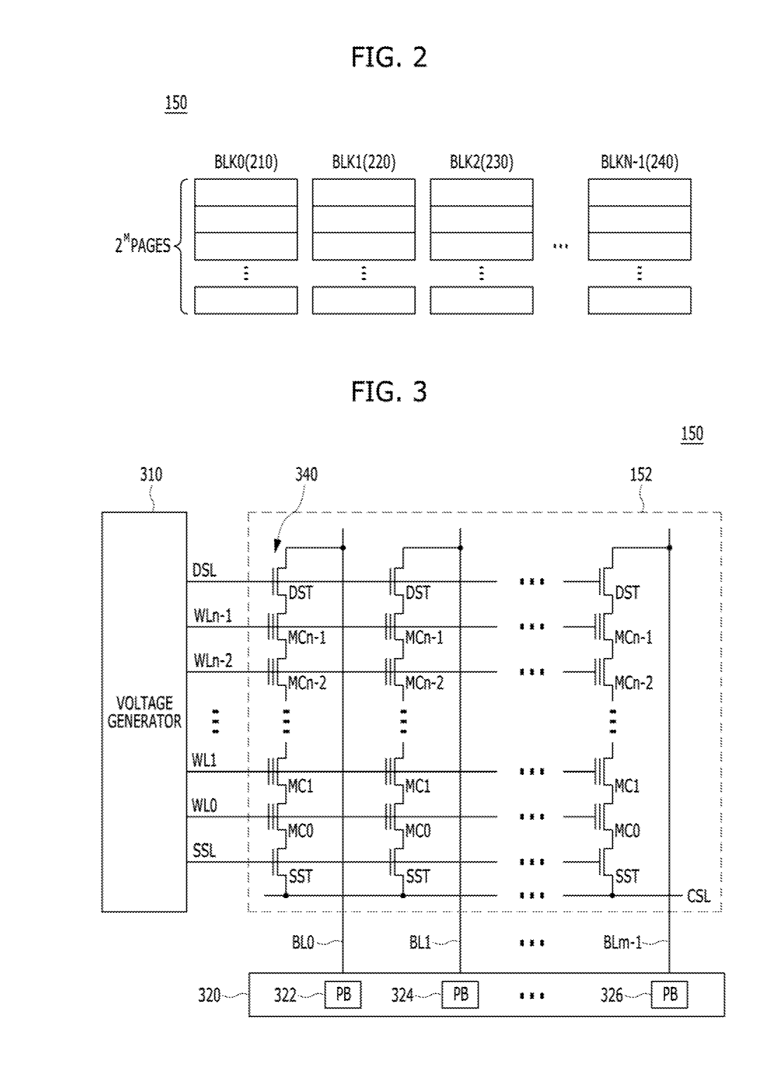

The memory device 150 may store data provided from the host 102. During a read operation, the memory device 150 may provide the stored data to the host 102. One or more memory devices 150 may be employed. The one or more memory devices 150 may be substantially identical. The one or more memory devices may be different memory devices. The memory device 150 may include one or more memory blocks 152, 154 and 156. Each of the memory blocks 152 154 and 156 may include a plurality of pages. Each of the pages may include a plurality of memory cells coupled electrically to a plurality of word lines (WL). The memory device 150 may be a nonvolatile memory device capable of retaining stored data even when a power supply is interrupted or turned off. According to an embodiment, the memory device may be a flash memory. The memory device may be a flash memory device having a three-dimensional (3D) stack structure. Examples of a non-volatile memory device 150 having a three-dimensional (3D) stack structure are described later herein with reference to FIGS. 2 to 11.

The controller 130 may control the overall operation of the memory device 150, such as, read, write, program and/or erase operations. Generally, the controller 130 may control the memory device 150 in response to a request from the host 102. For example, the controller 130 may provide data read from the memory device 150, to the host 102, in response to a read request from the host 102. Or, also as an example, the controller may store data provided from the host 102 into the memory device 150 in response to a write request.

Any suitable controller may be used. For example, the controller 130 may include a host interface unit 132, a processor 134, an error correction code (ECC) unit 138, a power management unit (PMU) 140, a NAND flash controller (NFC) 142, and a memory 144.

The host interface unit 132 may process commands and/or data provided from the host 102. The host interface unit 132 may communicate with the host 102 through at least one of various interface protocols, such as a universal serial bus (USB), a multimedia card (MMC), a peripheral component interconnect-express (PCI-E), a serial attached SCSI (SAS), a serial advanced technology attachment (SATA), a parallel advanced technology attachment (PATH), a small computer system interface (SCSI), an enhanced small disk interface (ESDI), integrated drive electronics (IDE) and the like. The host interface unit 132 may include any suitable circuits, systems or devices suitable for communicating with the host 102 and the other components of the controller 130 as may be needed.

The ECC unit 138 may detect and correct errors of the data read from the memory device 150 during a read operation. Various detection and correction techniques may be employed. For example, if the number of the error bits detected by the ECC unit 138 is greater than or equal to a threshold number of correctable error bits, the ECC unit 138 may not correct the error bits and output an error correction fail signal indicating failure in correcting the error bits.

The ECC unit 138 may perform an error correction operation based on any suitable error correction scheme. For example the ECC unit 138 may perform an error correction operation based on a coded modulation scheme such as, for example a low density parity check (LDPC) code, a Bose-Chaudhuri-Hocquenghem (BCH) code, a turbo code, a Reed-Solon (RS) code, a convolution code, a recursive systematic code (RSC), a trellis-coded modulation (TCM), a Block coded modulation (BCM), and the like. The ECC unit 138 may include any suitable circuits, systems or devices required for an error detection and correction operation.

The PMU 140 may provide and manage electric power for the controller 130. For example, the PMU 140 may provide and manage electric power for the various components of the controller 130 as may be needed. The PMU 140 may provide different voltage power to the various components of the controller as may be needed. The PMU 140 may provide same voltage power to the various components of the controller. The PMU may comprise any suitable circuits, systems and devices.

The NFC 142 may serve as a memory interface between the controller 130 and the memory device 150 to allow the controller 130 to control the memory device 150 in response to a request from the host 102. For example, the NFC 142 may generate control signals for the memory device 150. The NFC may process data under the control of the processor 134, for example, when the memory device 150 is a flash memory especially a NAND flash memory.

The memory 144 may serve as a working memory of the memory system 110 and the controller 130, and store data for driving the memory system 110 and the controller 130. For example, when the controller 130 controls the operations of the memory device 150, the memory 144 may store data used by the controller 130 and the memory device 150 for such operations as read, write, program and erase operations.

The memory 144 may be implemented with a volatile memory. For example, the memory 144 may be or comprise a static random access memory (SRAM) or a dynamic random access memory (DRAM). As described above, the memory 144 may store data used by the host 102 and the memory device 150 for read and/or write operations. The memory 144 may be or include a program memory, a data memory, a write buffer, a read buffer, a map buffer, and the like.

The processor 134 may control the general operations of the memory system 110. For example, the processor 134 may control a write operation for the memory device 150, in response to a write request from the host 102. Also, for example, the processor 134 may control a read operation for the memory device 150, in response to a read request from the host 102. The processor 134 may drive a firmware, also referred to as a flash translation layer (FTL), for controlling the general operations of the memory system 110. The processor 134 may be implemented with a microprocessor, a central processing unit (CPU) and the like. Any suitable processor may be used.

For example, a management unit (not shown) may be included in the processor 134 for performing bad block management of the memory device 150. Accordingly, the management unit may find bad memory blocks included in the memory device 150, i.e., memory blocks which are in an unsatisfactory condition for further use, and perform a bad block management operation the bad memory blocks. For example, when a flash memory, such as a NAND flash memory is employed as the memory device 150, a program failure may occur during a write operation due to inherent characteristics of a NAND logic function. During a bad block management, the data of the program-failed memory blocks (e.g., the bad memory blocks) may be programmed into a new memory block. The bad blocks due to a program fail may seriously deteriorate the utilization efficiency of a memory device, especially one having a 3D stack structure and thus negatively affect the reliability of the memory system 110.

Referring to FIG. 2 the memory device 150 may include a plurality of memory blocks, for example, zeroth to (N-1)^{th} blocks 210 to 240, where N is a positive integer. Each of the plurality of memory blocks 210 to 240 may include a plurality of pages, for example, 2^{M} number of pages (2^{M} PAGES), where M is a positive integer. Each of the plurality of pages may include a plurality of memory cells to which a plurality of word lines may be coupled electrically. It is noted that any number of suitable blocks and pages per block may be employed.

The memory blocks may be single level cell (SLC) memory blocks and/or multi-level cell (MLC) memory blocks, according to the number of bits which may be stored or expressed in each memory cell. An SLC memory block may include a plurality of pages which are implemented with memory cells each of which is capable of storing 1-bit data. An MLC memory block may include a plurality of pages which are implemented with memory cells each of which is capable of storing multi-bit data, for example, two or more-bit data. A MLC memory block including a plurality of pages which are implemented with memory cells each of which is capable of storing 3-bit data may be employed and will be referred to as a triple level cell (TLC) memory block.

Each of the plurality of memory blocks 210 to 240 may store data provided from the host device 102 during a write operation, and may provide stored data to the host 102 during a read operation.

Referring to FIG. 3, a memory block 152 of the memory device 150 may include a plurality of cell strings 340 coupled electrically to bit lines BL0 to BLm-1, respectively. Each cell string 340 may include at least one drain select transistor DST and at least one source select transistor SST. A plurality of memory cells or a plurality of memory cell transistors MC0 to MCn-1 may be coupled electrically in series between the select transistors DST and SST. The respective memory cells MC0 to MCn-1 may consist of multi-level cells (MLC) each of which stores data information of a plurality of bits. The memory cells may have any suitable architecture.

In FIG. 3, ‘DSL’ denotes a drain select line, ‘SSL’ denotes a source select line, and ‘CSL’ denotes a common source line.

FIG. 3 shows, as an example, a memory block 152 configured by NAND flash memory cells. It is to be noted, however, that the memory block 152 is not limited to NAND flash memory and may be realized, in other embodiments, by NOR flash memory, hybrid flash memory having at least two kinds of memory cells combined, or a NAND flash memory having a controller built in a memory chip. Also, the operational characteristics of a semiconductor device may be applied to not only a flash memory device in which a charge storing layer is configured by conductive floating gates but also to a charge trap flash (CTF) in which a charge storing layer is configured by a dielectric layer.

It is also noted that the memory device 150 is not limited to a flash memory device only. For example, the memory device 150 may be a DRAM or a SRAM device.

A voltage generator 310 of the memory device 150 may generate word line voltages, for example, a program voltage, a read voltage or a pass voltage, to be supplied to respective word lines according to an operation mode. The voltage generator 310 may generate voltages to be supplied to bulks, for example, well regions in which the memory cells are formed. The voltage generator 310 may perform a voltage generating operation under a control of a control circuit (not shown). The voltage generator 310 may generate a plurality of variable read voltages to generate a plurality of read data. The voltage generator 310 may select one of the memory blocks or sectors of a memory cell array, select one of the word lines of the selected memory block, and provide the word line voltages to the selected word line and unselected word lines, under the control of the control circuit.

A read/write circuit 320 of the memory device 150 may be controlled by the control circuit and may serve as a sense amplifier or a write driver according to an operation mode. During a verification/normal read operation, the read/write circuit 320 may serve as a sense amplifier for reading data from the memory cell array. Also, during a program operation, the read/write circuit 320 may serve as a write driver for driving bit lines according to data to be stored in the memory cell array. The read/write circuit 320 may receive data to be written in the memory cell array, from a buffer (not shown), during the program operation, and may drive the bit lines according to the inputted data. To this end, the read/write circuit 320 may include a plurality of page buffers 322, 324 and 326 respectively corresponding to the columns (or bit lines) or pairs of the columns (or pairs of bit lines). Each of the page buffers 322, 324 and 326 may include a plurality of latches (not shown).

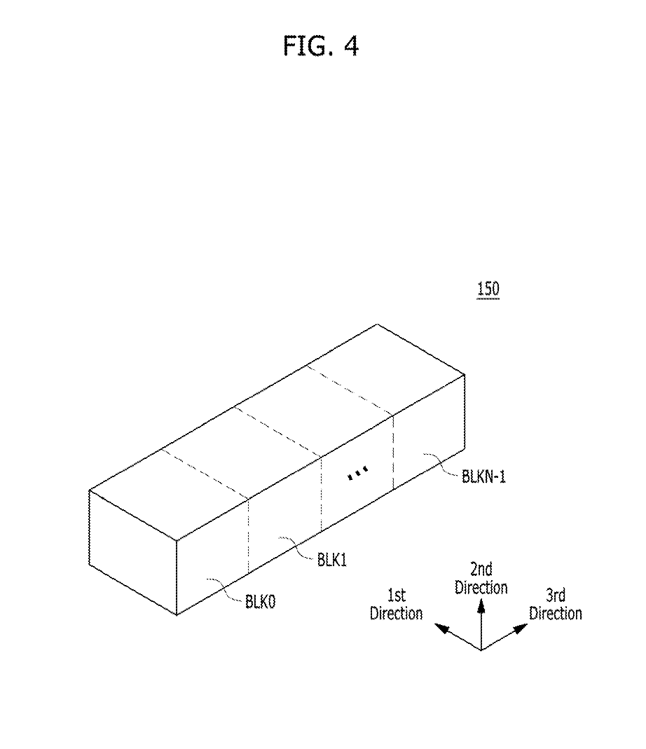

FIG. 4 is a block diagram illustrating an example of the plurality of memory blocks 152 to 156 of the memory device 150, according to an embodiment of the present invention.

As shown in FIG. 4, the memory device 150 may include a plurality of memory blocks BLK0 to BLKN-1. Each of the memory blocks BLK0 to BLKN-1 may be realized in a 3D structure or a vertical structure. The respective memory blocks BLK0 to BLKN-1 may include a plurality of structures extending in first to third directions, for example, an x-axis direction, a y-axis direction and a z-axis direction.

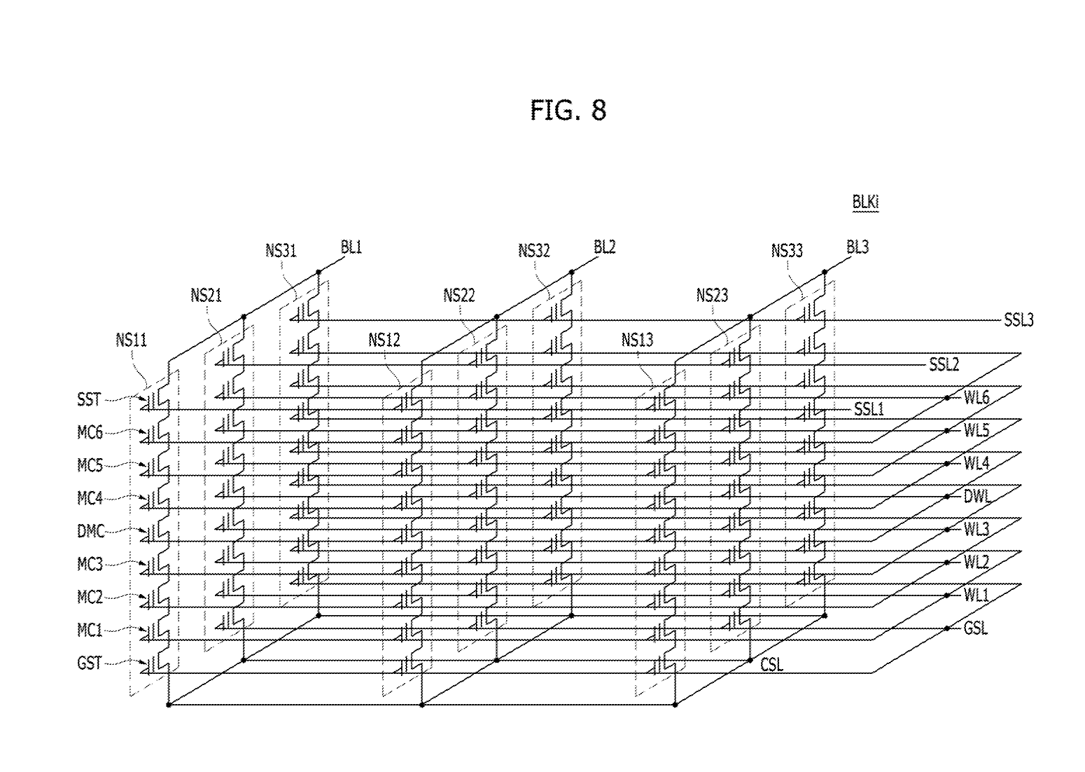

The respective memory blocks BLK0 to BLKN-1 may include a plurality of NAND strings NS extending in the second direction (FIG. 8). The plurality of NAND strings NS may be provided in the first direction and the third direction. Each NAND string NS may be coupled electrically to a bit line BL, at least one source select line SSL, at least one ground select line GSL, a plurality of word lines WL, at least one dummy word line DWL, and a common source line CSL. The respective memory blocks BLK0 to BLKN-1 may be coupled electrically to a plurality of bit lines BL, a plurality of source select lines SSL, a plurality of ground select lines GSL, a plurality of word lines WL, a plurality of dummy word lines DWL, and a plurality of common source lines CSL.

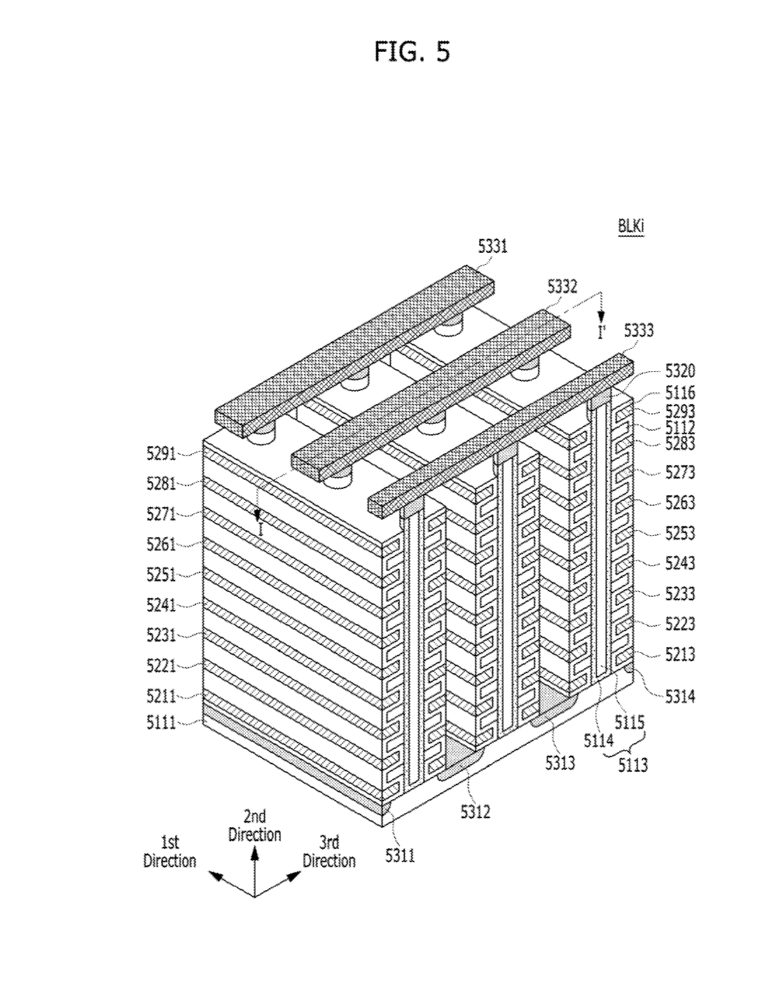

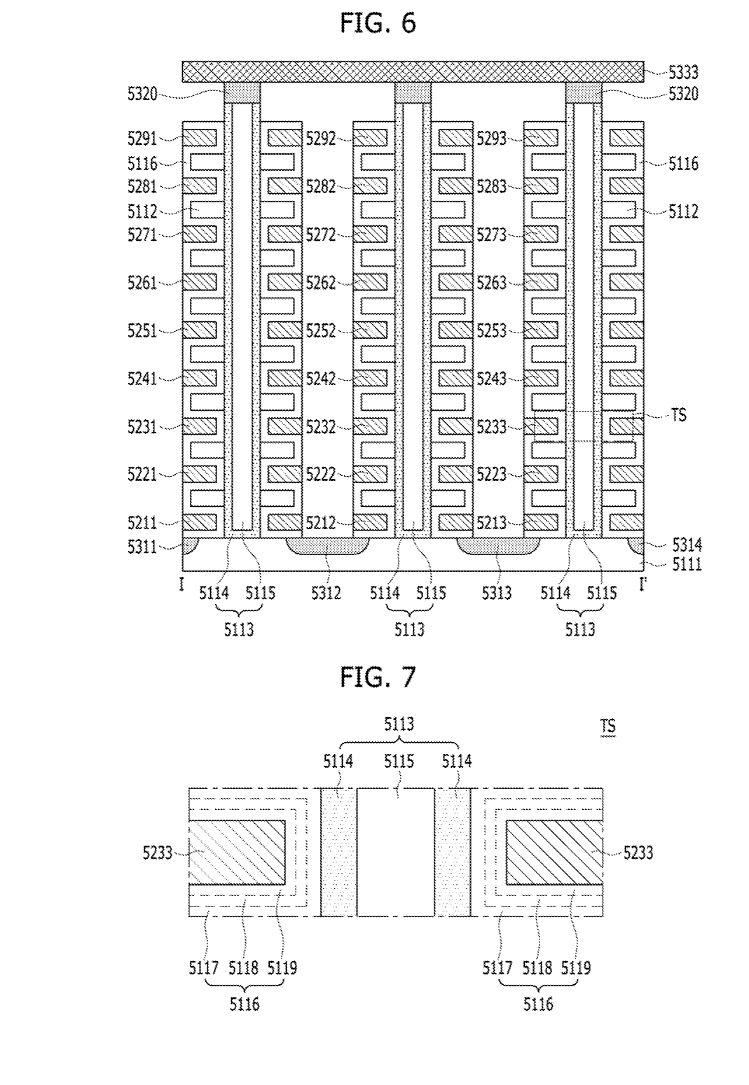

FIG. 5 is a perspective view of one memory block BLKi of the plurality memory blocks BLK0 to BLKN-1 shown in FIG. 4. FIG. 6 is a cross-sectional view taken along a line I-I′ of the memory block BLKi shown in FIG. 5.

Referring to FIGS. 5 and 6, memory block BLKi may include a structure extending in the first to third directions.

The memory block may include a substrate 5111 including a silicon material doped with a first type impurity. For example, the substrate 5111 may include a silicon material doped with a p-type impurity. The substrate 5111 may be a p-type well, for example, a pocket p-well. The substrate 5111 may further include an n-type well surrounding the p-type well. Although, in the embodiment of the present invention, the substrate 5111 is exemplified as being the p-type silicon, it is to be noted that the substrate 5111 is not limited to the p-type silicon.

A plurality of doping regions 5311 to 5314 extending in the first direction may be provided over the substrate 5111. The doping regions are spaced apart at regular intervals in the third direction. The plurality of doping regions 5311 to 5314 may contain a second type impurity that is different from that of the impurity used in substrate 5111. For example, the plurality of doping regions 5311 to 5314 may be doped with an n-type impurity. Although, in the embodiment of the present invention, first to fourth doping regions 5311 to 5314 are exemplified as being the n-type, it is noted that they are not limited to the n-type.

In the region over the substrate 5111 between the first and second doping regions 5311 and 5312, a plurality of dielectric material regions 5112 extending in the first direction may be spaced apart at regular intervals in the second direction. The dielectric material regions 5112 may also be separated from the substrate 5111 by a preset distance in the second direction. Each of the dielectric material regions 5112 may be separated from one other by a preset distance in the second direction. The dielectric materials 5112 may include any suitable dielectric material, such as, silicon oxide.

In the regions over the substrate 5111 between two consecutive doping regions, for example, between doping regions 5311 and 5312, a plurality of pillars 5113 are spaced apart at regular intervals in the first direction. The plurality of pillars 5113 extend in the second direction and may pass through the dielectric material regions 5112 so that they may be coupled electrically with the substrate 5111 Each pillar 5113 may include one or more materials. For example, each pillar 5113 may include an in inner layer 5115 and an outer surface layer 5114. The surface layer 5114 may include a doped silicon material doped with an impurity. For example, the surface layer 5114 may include a silicon material doped with the same or same type impurity as the substrate 5111. Although, in the embodiment of the present invention, the surface layer 5114 is exemplified as including p-type silicon, the surface layer 5114 is not limited to the p-type silicon and other embodiments may readily envisaged by the skilled person wherein the substrate 5111 and the surface layer 5114 of the pillars 5113 may be doped with an n-type impurity.

The inner layer 5115 of each pillar 5113 may be formed of a dielectric material. The inner layer 5115 may be or include a dielectric material such as silicon oxide.

In the regions between the first and second doping regions 5311 and 5312 a dielectric layer 5116 may be provided along exposed surfaces of the dielectric material regions 5112, the pillars 5113 and the substrate 5111. A thickness of the dielectric layer 5116 may be less than one half of the distance between the dielectric material regions 5112. In other words, a region of a material other than the dielectric material 5112 and the dielectric layer 5116 may be provided between (i) the dielectric layer 5116 below the bottom surface of a first dielectric material the dielectric material regions 5112 and (ii) the dielectric layer 5116 provided over the top surface of a second dielectric material of the dielectric material regions 5112. The dielectric material regions 5112 may lie below the first dielectric material.

In the regions between consecutive doping regions such as in the region between the first and second doping regions 5311 and 5312, a plurality of conductive material regions 5211 to 5291 may be provided over an exposed surface of the dielectric layer 5116. The plurality of the conductive material regions extending in the first direction may be spaced apart at regular intervals in the second direction in an interleaving configuration with the plurality of the dielectric material regions 5112. The dielectric layers 5116 fill the space between the conductive material regions and the dielectric material regions 5112. So for example, the conductive material region 5211 extending in the first direction may be provided between the dielectric material region 5112 adjacent to the substrate 5111 and the substrate 5111. In particular, the conductive material region 5211 extending in the first direction may be provided between (i) the dielectric layer 5116 disposed over the substrate 5111 and (ii) the dielectric layer 5116 disposed below the bottom surface of the dielectric material region 5112 adjacent to the substrate 5111.

Each of the conductive material regions 5211 to 5291 extending in the first direction may be provided between (i) a dielectric layer 5116 disposed over the top surface of one of the dielectric material regions 5112 and the dielectric layer 5116 disposed below the bottom surface of the next dielectric material region 5112. The conductive material regions 5221 to 5281 extending in the first direction may be provided between the dielectric material regions 5112. The top conductive material region 5291 extending in the first direction may be provided over the uppermost dielectric material 5112. The conductive material regions 5211 to 5291 extending in the first direction may be made of or include a metallic material. The conductive material regions 5211 to 5291 extending in the first direction may be made of or include a conductive material such as polysilicon.

In the region between the second doping region 5312 and third doping region 5313, the same structures as the structures between the first and second doping regions 5311 and 5312 may be provided. For example, in the region between the second and third doping regions 5312 and 5313, the plurality of dielectric material regions 5112 extending in the first direction, the plurality of pillars 5113 which are sequentially arranged in the first direction and, pass through the plurality of dielectric material regions 5112 in the second direction the dielectric layer 5116 which is provided over the exposed surfaces of the plurality of dielectric material regions 5112 and the plurality of pillars 5113, and the plurality of conductive material regions 5212 to 5292 extending in the first direction may be provided.

In the region between the third doping region 5313 and a fourth doping region 5314, the same structures as between the first and second doping regions 5311 and 5312 may be provided. For example, in the region between the third and fourth doping regions 5313 and 5314, the plurality of dielectric material regions 5112 extending in the first direction, the plurality of pillars 5113 which are sequentially arranged in the first direction and pass through the plurality of dielectric material regions 5112 in the second direction, the dielectric layer 5116 which is provided over the exposed surfaces of the plurality of dielectric material regions 5112 and the plurality of pillars 5113, and the plurality of conductive material regions 5213 to 5293 extending in the first direction may be provided.

Drains 5320 may be respectively provided over the plurality of pillars 5113. The drains 5320 may be made of silicon materials doped with second type impurities. The drains 5320 may be made of silicon materials doped with n-type impurities. Although for the sake of convenience of explanation, the drains 5320 are exemplified as including n-type silicon, it is noted that the drains 5320 are not limited to the n-type silicon. For example, the width of each drain 5320 may be larger than the width of each corresponding pillar 5113. Each drain 5320 may be provided in the shape of a pad over the top surface of each corresponding pillar 5113.

Conductive material regions 5331 to 5333 extending in the third direction may be provided over the drains 5320. Each of the conductive material regions 5331 to 5333 may be extendedly disposed over the drains 5320 serially arranged in the third direction with a preset separation distance to each other in the first direction. The respective conductive material regions 5331 to 5333 may be coupled electrically with, the drains 5320 therebelow. The drains 5320 and the conductive material regions 5331 to 5333 extending in the third direction may be coupled electrically with through contact plugs. The conductive material regions 5331 to 5333 extending in the third direction may be made of a metallic material. The conductive material regions 5331 to 5333 extending in the third direction may be made of a conductive material such as polysilicon.

In FIGS. 5 and 6, the respective pillars 5113 may form strings together with the dielectric layer 5116 and the conductive material regions 5211 to 5291, 5212 to 5292 and 5213 to 5293 extending in the first direction. The respective pillars 5113 may form NAND strings NS together with the dielectric layer 5116 and the conductive material regions 5211 to 5291, 5212 to 5292 and 5213 to 5293 extending in the first direction. Each NAND string NS may include a plurality of transistor structures TS.

Referring now to FIG. 7 in the transistor structure TS shown in FIG. 6, the dielectric layer 5116 may include first to third sub dielectric layers 5117, 5118 and 5119.

The surface layer 5114 of p-type silicon in each of the pillars 5113 may serve as a body. The first sub dielectric layer 5117 adjacent to the pillar 5113 may serve as a tunneling dielectric layer, and may include a thermal oxidation layer.

The second sub dielectric layer 5118 may serve as a charge storing layer. The second sub dielectric layer 5118 may serve as a charge capturing layer, and may include a nitride layer or a metal oxide layer such as an aluminum oxide layer a hafnium oxide layer, or the like.

The third sub dielectric layer 5119 adjacent to the conductive material 5233 may serve as a blocking dielectric layer. The third sub dielectric layer 5119 adjacent to the conductive material 5233 extending in the first direction may be formed as a single layer or multiple layers. The third sub dielectric layer 5119 may be a high-k dielectric layer such as an aluminum oxide layer, a hafnium oxide layer, or the like, which has a dielectric constant greater than the first and second sub dielectric layers 5117 and 5118.

The conductive material 5233 may serve as a gate or a control gate. For example, the gate or the control gate 5233, the blocking dielectric layer 5119, the charge storing layer 5118, the tunneling dielectric layer 5117 and the body 5114 may form a transistor or a memory cell transistor structure. For example, the first to third sub dielectric layers 5117 to 5119 may form an oxide-nitride-oxide (ONO) structure. In the embodiment, for the sake of convenience of explanation, the surface layer 5114 of p-type silicon in each of the pillars 5113 will be referred to as a body in the second direction.

The memory block BLKi may include the plurality of pillars 5113. For example, the memory block BLKi may include the plurality of NAND strings NS. In detail, the memory block BLKi may include the plurality of NAND strings NS extending in the second direction or a direction perpendicular to the substrate 5111.

Each NAND string NS may include the plurality of transistor structures TS which are disposed in the second direction. At least one of the plurality of transistor structures TS of each NAND string NS may serve as a string source transistor SST. At least one of the plurality of transistor structures TS of each NAND string NS may serve as a ground select transistor GST.

The gates or control gates may correspond to the conductive material regions 5211 to 5291, 5212 to 5292 and 5213 to 5293 extending in the first direction. For example, the gates or the control gates may extend in the first direction and form word lines and at least two select lines including at least one source select line SSL and at least one ground select line GSL.

The conductive material regions 5331 to 5333 extending in the third direction may be coupled electrically to one end of the NAND strings NS. The conductive material regions 5331 to 5333 extending in the third direction may serve as bit lines BL. For example, in one memory block BLKi, the plurality of NAND stings NS may be coupled electrically to one-bit line BL.

The second type doping regions 5311 to 5314 extending in the first direction may be provided to the other ends of the NAND strings NS. The second type doping regions 5311 to 5314 extending in the first direction may serve as common source lines CSL.

For example, the memory block BLKi may include a plurality of NAND strings NS extending in a direction perpendicular to the substrate 5111, e.g., the second direction, and may serve as a NAND flash memory block, for example, of a charge capturing type memory, in which the plurality of NAND strings NS are coupled electrically to one-bit line BL.

Although it is illustrated in FIGS. 5 to 7 that the conductive material regions 5211 to 5291, 5212 to 5292 and 5213 to 5293 extending in the first direction are provided by nine (9) layers, it is noted that the conductive material regions 5211 to 5291, 5212 to 5292 and 5213 to 5293 extending in the first direction are not limited thereto. For example, conductive material regions extending in the first direction may be provided in eight (8) layers, sixteen (16) layers or any multiple layers. For example, in one NAND string NS, the number of transistors may be 8, 16 or more.

Although it is illustrated in FIGS. 5 to 7 that three (3) NAND strings NS are coupled electrically to one-bit line BL, it is noted that the embodiment is not limited thereto. In the memory block BLKi, m NAND strings NS may be coupled electrically to one-bit line BL, m being a positive integer. The number of conductive material regions 5211 to 5291, 5212 to 5292 and 5213 to 5293 extending in the first direction and the number of common source lines 5311 to 5314 may be varied with the number of NAND strings NS which are coupled electrically to one-bit line BL.

Further, although it is illustrated in FIGS. 5 to 7 that three (3) NAND strings NS are coupled electrically to one conductive material extending in the first direction, it is noted that the embodiment is not limited thereto. For example, n NAND strings NS may be coupled electrically to one conductive material extending in the first direction, n being a positive integer. The number of bit lines 5331 to 5333 may be varied with the number of NAND strings NS which are coupled electrically to one conductive material extending in the first direction.

Referring to FIG. 8, in a block BLKi having the first structure, a plurality of NAND strings NS11 to NS31 may be provided between a first bit line BL1 and a common source line CSL. The first bit line BL1 may correspond to the conductive material region 5331 of FIGS. 5 and 6, extending in the third direction. NAND strings NS12 to NS32 may be provided between a second bit line BL2 and the common source line CSL. The second bit line BL2 may correspond to the conductive material region 5332 of FIGS. 5 and 6 extending in the third direction. NAND strings NS13 to NS33 may be provided between a third bit line BL3 and the common source line CSL. The third bit line BL3 may correspond to the conductive material region 5333 of FIGS. 5 and 6, extending in the third direction.

A source select transistor SST of each NAND string NS may be coupled electrically to a corresponding bit line BL. A ground select transistor GST of each NAND string NS may be coupled electrically to the c on source line CSL. Memory cells MC1 and MC6 may be provided between the source select transistor SST and the ground select transistor GST of each NAND string NS.

In this example, the NAND strings NS may be defined by units of rows and columns. The NAND strings NS which are coupled electrically to one-bit line may form one column. The NAND strings NS11 to NS31 which are coupled electrically to the first bit line BL1 may correspond to a first column. The NAND strings NS12 to NS32 which are coupled electrically to the second bit line BL2 may correspond to a second column. The NAND strings NS13 to NS33 which are coupled electrically to the third bit line BL3 may correspond to a third column. The NAND strings NS which are coupled electrically to one source select line SSL may form one row. The NAND strings NS11 to NS13 which are coupled electrically to a first source select line SSL1 may form a first row. The NAND strings NS21 to NS23 which are coupled electrically to a second source select line SSL2 may form a second row. The NAND strings NS31 to NS33 which are coupled electrically to a third source select line SSL3 may form a third row.

In each NAND string NS, a height may be defined. In each NAND string NS, the height of the memory cell MC1 adjacent to the ground select transistor GST may have, for example, a value ‘1’. In each NAND string NS, the height of a memory cell may increase as the memory cell gets closer to the source select transistor SST when measured from the substrate 5111. For example, in each NAND string NS the height of a memory cell MC6 adjacent to the source select transistor SST may have, for example, a value ‘7’.

The source select transistors SST of the NAND strings NS arranged in the same row may share the source select line SSL. The source select transistors SST of the NAND strings NS arranged in different rows may be respectively coupled electrically to the different source select lines SSL1, SSL2 and SSL3.

The memory cells at the same height in the NAND strings NS in to the same row may share a word line WL. For example, at the same height, the word lines WL coupled electrically to the memory cells MC of the NAND strings NS in different rows may be coupled electrically with each other. Dummy memory cells DMC at the same height in the NAND strings NS of the same row may share a dummy word line DWL. For example, at the same height or level, the dummy word lines DWL coupled electrically to the dummy memory cells DMC of the NAND strings NS in different rows may be coupled electrically with each other.

The word lines WL or the dummy word lines DWL located at the same level or height or layer may be coupled electrically with each other for each of layers where the conductive material regions 5211 to 5291, 5212 to 5292 and 5213 to 5293 extending in the first direction may be provided. The conductive material regions 5211 to 5291, 5212 to 5292 and 5213 to 5293 extending in the first direction may be coupled electrically in common to upper layers through contacts. In other words, the ground select transistors GST of the NAND strings NS in the same row may share the ground select line GSL. Further, the ground select transistors GST of the NAND strings NS in different rows may share the ground select line GSL. For example, the NAND strings NS11 to NS13, NS21 to NS23 and NS31 to NS33 may be coupled electrically in common to the ground select line GSL.

The common source line CSL may be coupled electrically in common to the NAND strings NS. Over the active regions over the substrate 5111, the first to fourth doping regions 5311 to 5314 may be coupled electrically. The first to fourth doping regions 5311 to 5314 may be coupled electrically in common to an upper layer through contacts,

For example, as shown in FIG. 8, the word lines WL of the same height or level may be coupled electrically to each other. Accordingly, when a word line WL at a certain height is selected, all NAND strings NS which are coupled electrically to the selected word line WL may be selected. The NAND strings NS in different rows may be coupled electrically to different source select lines SSL. Accordingly, among the NAND strings NS coupled electrically to the same word line WL, by selecting one of the source select lines SSL1 to SSL3, the NAND strings NS in the unselected rows may be electrically isolated from the bit lines BL1 to BL3. In other words, by selecting one of the source select lines SSL1 to SSL3, the NAND strings NS arranged in the same row as the selected source line may be selected. Furthermore, by selecting one of the bit lines BL1 to BL3, the NAND strings NS arranged in the same column as the selected bit line may be selected. Accordingly, only the NAND strings NS arranged in the same row as the selected source line and the same column as the selected bit line may be selected.

In each NAND string NS, a dummy memory cell DMC may be provided. In FIG. 8, for example, the dummy memory cell DMC may be provided between a third memory cell MC3 and a fourth memory cell MC4 in each NAND string NS. For example, first to third memory cells MC1 to MC3 may be provided between the dummy memory cell DMC and the ground select transistor GST. Fourth to sixth memory cells MC4 to MC6 may be provided between the dummy memory cell DMC and the source select transistor SST. The memory cells MC of each NAND string NS may be divided into two (2) memory cell groups by the dummy memory cell DMC. In the divided memory cell groups, memory cells, for example, MC1 to MC3, adjacent to the ground select transistor GST may be referred to as a lower memory cell group, and remaining memory cells, for example, MC4 to MC6, adjacent to the string select transistor SST may be referred to as an upper memory cell group.

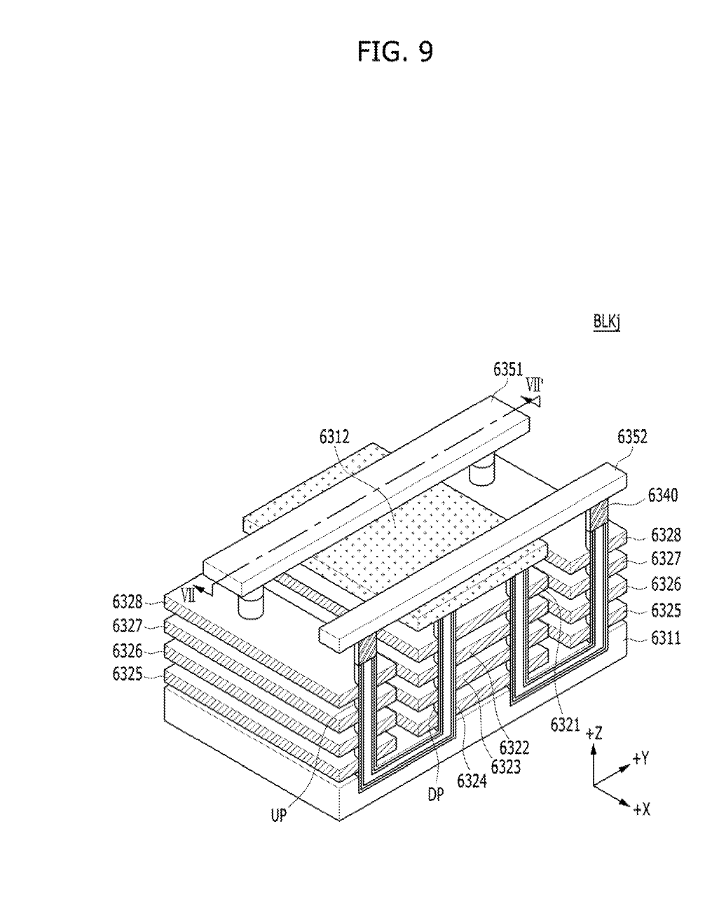

Herein below detailed descriptions will be made with reference to FIGS. 9 to 11, which show a memory device in a memory system, according to an embodiment implemented with a three-dimensional (3D) nonvolatile memory device different from the first structure.

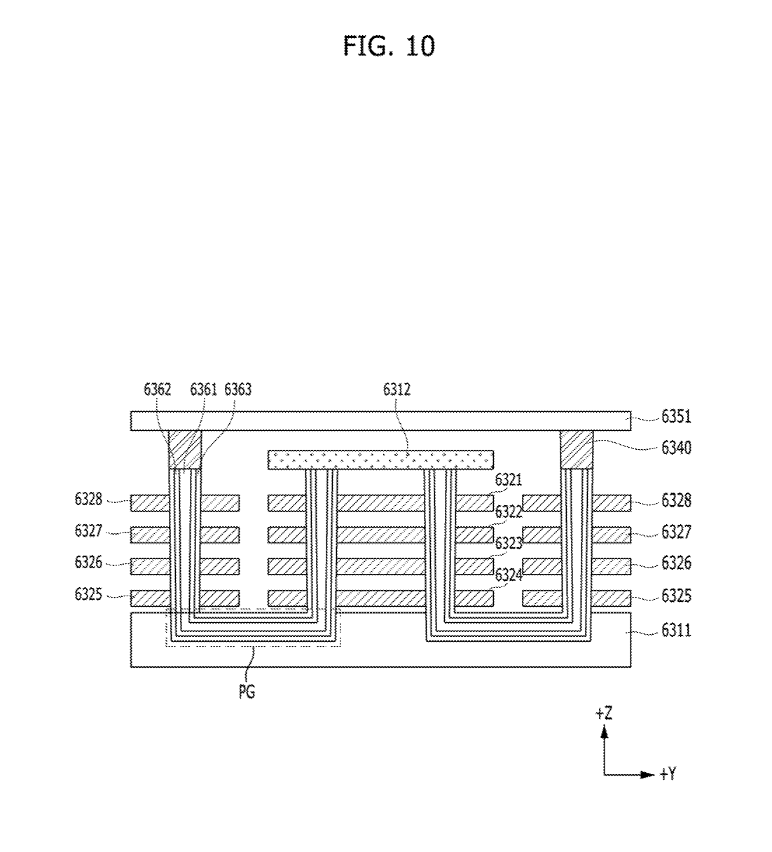

FIG. 9 is a perspective view schematically illustrating a memory device implemented with a three-dimensional (3D) nonvolatile memory device, which is different from the first structure described above with reference to FIGS. 5 to 8 and showing a memory block BLKj of the plurality of memory blocks of FIG. 4. FIG. 10 is a cross-sectional view illustrating the memory block BLKj taken along the line VII-VII′ of FIG. 9.

Referring to FIGS. 9 and 10, the memory block BLKj may include structures extending in the first to third directions and may include a substrate 6311. The substrate 6311 may include a silicon material doped with a first type impurity. For example, the substrate 6311 may include a silicon material doped with a p-type impurity. The substrate 6311 may be a p-type well, for example, a pocket p-well. The substrate 6311 may further include an n-type well which surrounds the p-type well. Although, in the described embodiment, the substrate 6311 is exemplified as being the p-type silicon, it is noted that the substrate 6311 is not limited to the p-type silicon.

First to fourth conductive material regions 6321 to 6324 extending in an x-axis direction and a y-axis direction are provided over the substrate 6311. The first to fourth conductive material regions 6321 to 6324 may be separated by a preset distance in the z-axis direction.

Fifth to eighth conductive material regions 6325 to 6328 extending in the x-axis direction and the y-axis direction may be provided over the substrate 6311. The fifth to eighth conductive material regions 6325 to 6328 may be separated by the preset distance in the z-axis direction. The fifth to eighth conductive material regions 6325 to 6328 may be separated from the first to fourth conductive material regions 6321 to 6324 in the y-axis direction.

A plurality of lower pillars DP passing through the first to fourth conductive material regions 6321 to 6324 may be provided. Each lower pillar DP may extend in the z-axis direction. Also, a plurality of upper pillars UP passing through the fifth to eighth conductive material regions 6325 to 6328 may be provided. Each upper pillar UP may extend in the z-axis direction.

Each of the lower pillars DP and the upper pillars UP may include an internal material 6361, an intermediate layer 6362, and a surface layer 6363. The intermediate layer 6362 may serve as a channel of the cell transistor. The surface layer 6363 may include a blocking dielectric layer, a charge storing layer and a tunneling dielectric layer.

The lower and the upper pillars DP and UP may be coupled electrically with each other through a pipe gate PG. The pipe gate PG may be disposed in the substrate 6311. For example, the pipe gate PG may include the same material as the lower pillar DP and the upper pillar UP.

A doping material 6312 of a second type extending in the x-axis direction and the y-axis direction may be provided over the lower pillars DP. For example, the doping material 6312 of the second type may include an n-type silicon material. The doping material 6312 of the second type may serve as a common source line CSL.

Drains 6340 may be provided over the upper pillars UP. The drains 6340 may include an n-type silicon material. First and second upper conductive material regions 6351 and 6352 extending in the y-axis direction may be provided over the drains 6340.

The first and second upper conductive material regions 6351 and 6352 may be spaced apart along the x-axis direction. The first and second upper conductive material regions 6351 and 6352 may be formed of a metal. The first and second upper conductive material to regions 6351 and 6352 and the drains 6340 may be coupled electrically with each other through contact plugs. The first and second upper conductive material regions 6351 and 6352 may serve as first and second bit lines BL1 and BL2, respectively.

The first conductive material 6321 may serve as a source select line SSL. The second conductive material 6322 may serve as a first dummy word line DWL1. The third and fourth conductive material regions 6323 and 6324 may serve as first and second main word lines MWL1 and MWL2 respectively. The fifth and sixth conductive material regions 6325 and 6326 may serve as third and fourth main word lines MWL3 and MWL4, respectively. The seventh conductive material 6327 may serve as a second dummy word line DWL2. The eighth conductive material 6328 may serve as a drain select line DSL.

The lower pillar DP and the first to fourth conductive material regions 6321 to 6324 adjacent to the lower pillar DP may form a lower string. The upper pillar UP and the fifth to eighth conductive material regions 6325 to 6328 adjacent to the upper pillar UP may form an upper string. The lower string and the upper string may be coupled electrically with each other through the pipe gate PG. One end of the lower string may be coupled electrically to the doping material 6312 of the second type which serves as the common source line CSL. One end of the upper string may be coupled electrically to a corresponding bit line through the drain 6340. One lower string and one upper string may form one cell string which is coupled electrically between the doping material 6312 serving as the common source line CSL and a corresponding one of the upper conductive material layers 6351 and 6352 serving as the bit line BL.

For example, the lower string may include a source select transistor SST, the first dummy memory cell DMC1, and the first and second main memory cells MMC1 and MMC2. The upper string may include the third and fourth main memory cells MMC3 and MMC4, the second dummy memory cell DMC2, and a drain select transistor DST.

In FIGS. 9 and 10, the upper string and the lower string may form a NAND string NS. The NAND string NS may include a plurality of transistor structures TS. Since the transistor structure included in the NAND string NS in FIGS. 9 and 10 is described above in detail with reference to FIG. 7, a detailed description thereof will be omitted herein.

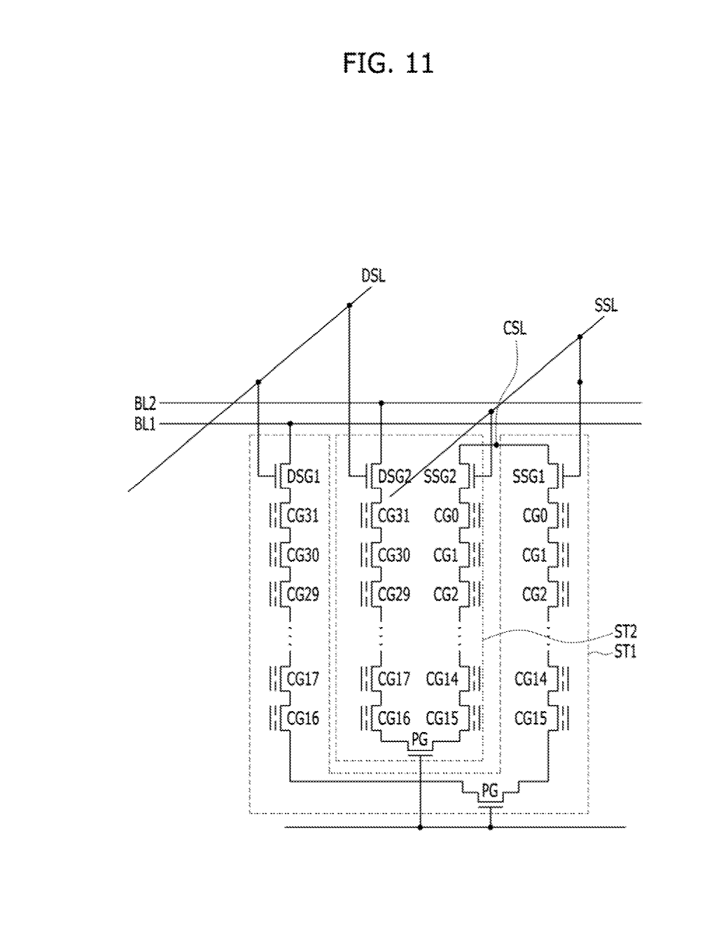

FIG. 11 is a circuit diagram illustrating the equivalent circuit of the memory block BLKj having the second structure as described above with reference to FIGS. 9 and 10. For the sake of convenience, only a first string ST1 and a second string ST2 are shown, forming a pair in the memory block BLKj in the second structure.

Referring to FIG. 11, in the memory block BLKj having the second structure, a plurality of cell strings, each of which is implemented with one upper string and one lower string coupled electrically through the pipe gate PG as described above with reference to FIGS. 9 and 10, may be provided, in such a way as to define a plurality of pairs.

For example, in memory block BLKj having the second structure, memory cells CG0 to CG31 stacked along a first channel CH1 (not shown), for example, at least one source select gate SSG1 and at least one drain select gate DSG1 may form a first string ST1, and memory cells CG0 to CG31 stacked along a second channel CH2 (not shown), for example, at least one source select gate SSG2 and at least one drain select gate DSG2 may form a second string ST2.

The first and the second strings ST1 and ST2 may be coupled electrically to the same drain select line DSL and the same source select line SSL. The first string ST1 may be coupled electrically to a first bit line BL. The second string ST2 may be coupled electrically to a second bit line BL2.

Although FIG. 11 shows the first string ST1 and the second string ST2 are coupled electrically to the same drain select line DSL and the same source select line SSL, it may be envisaged that the first string ST1 and the second string ST2 may be coupled electrically to the same source select line SSL and the same bit line BL, the first string ST1 may be coupled electrically to a first drain select line DSL1 and the second string ST2 may be coupled electrically to a second drain select line DSL2. Further it may be envisaged that the first string ST1 and the second string ST2 may be coupled electrically to the same drain select line DSL and the same bit line BL, the first string ST1 may be coupled electrically to a first source select line SSL1 and the second string ST2 may be coupled electrically a second source select line SSL2.

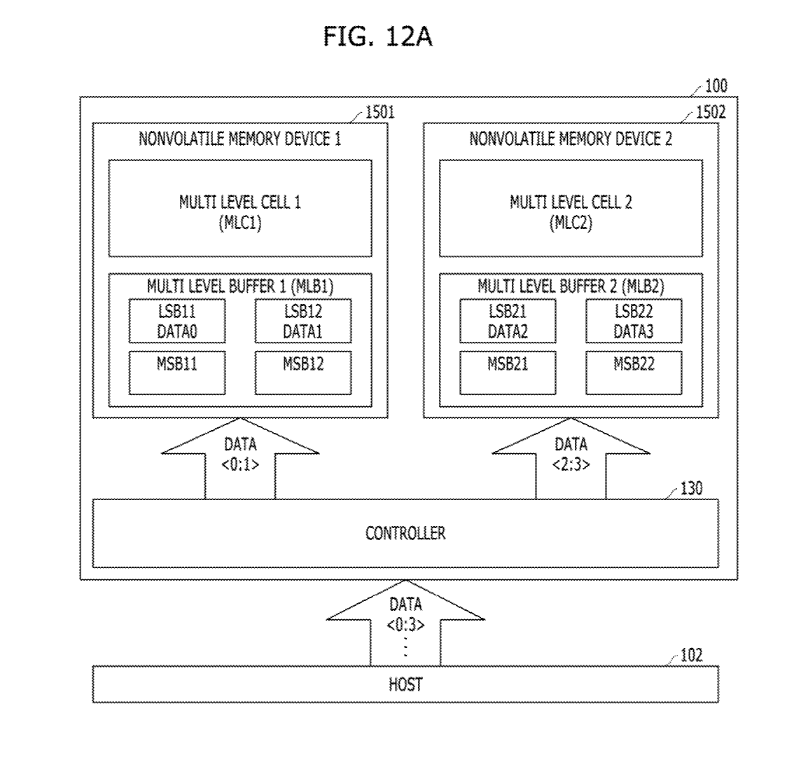

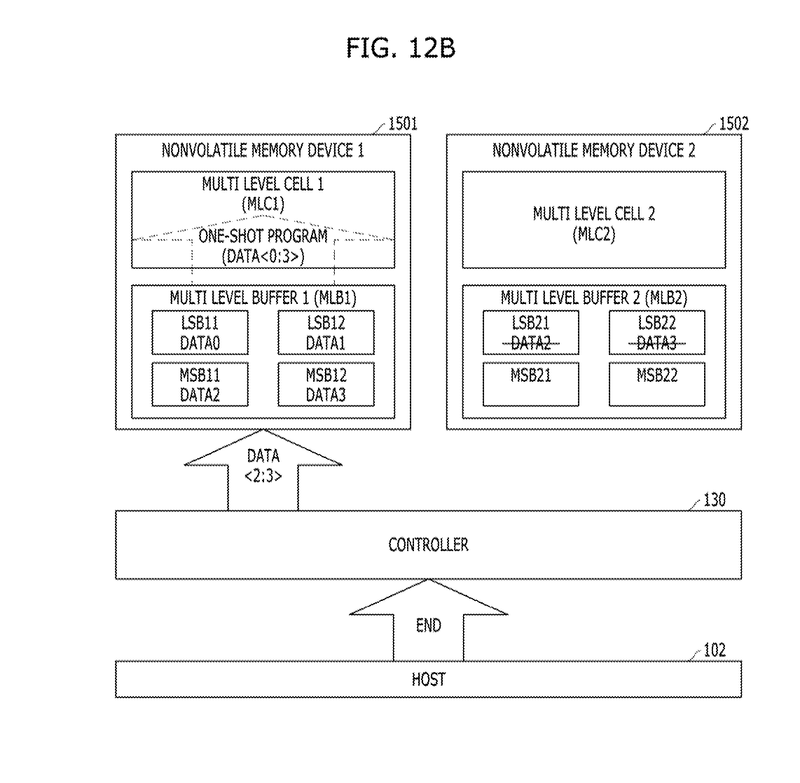

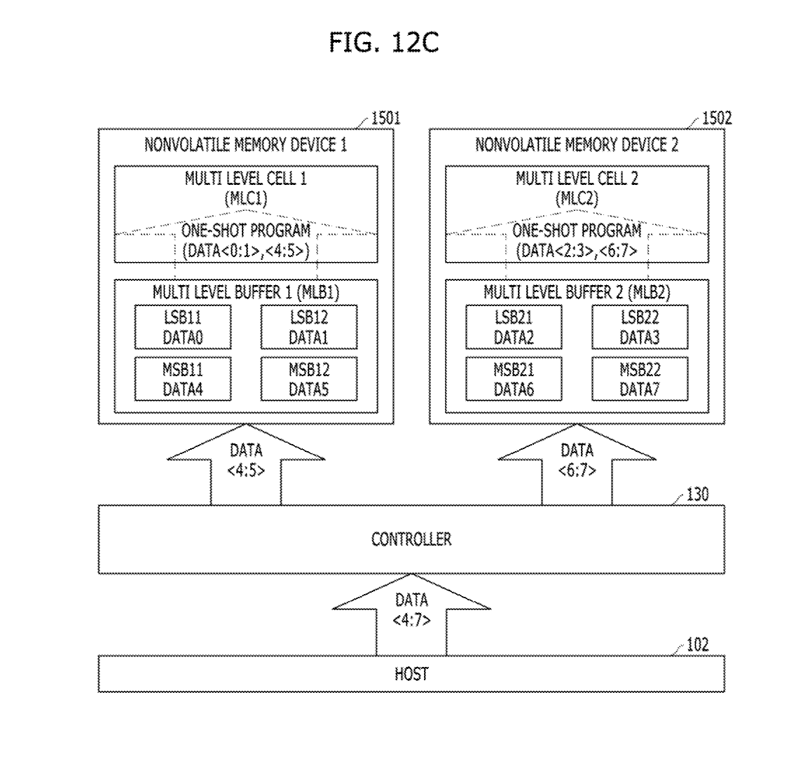

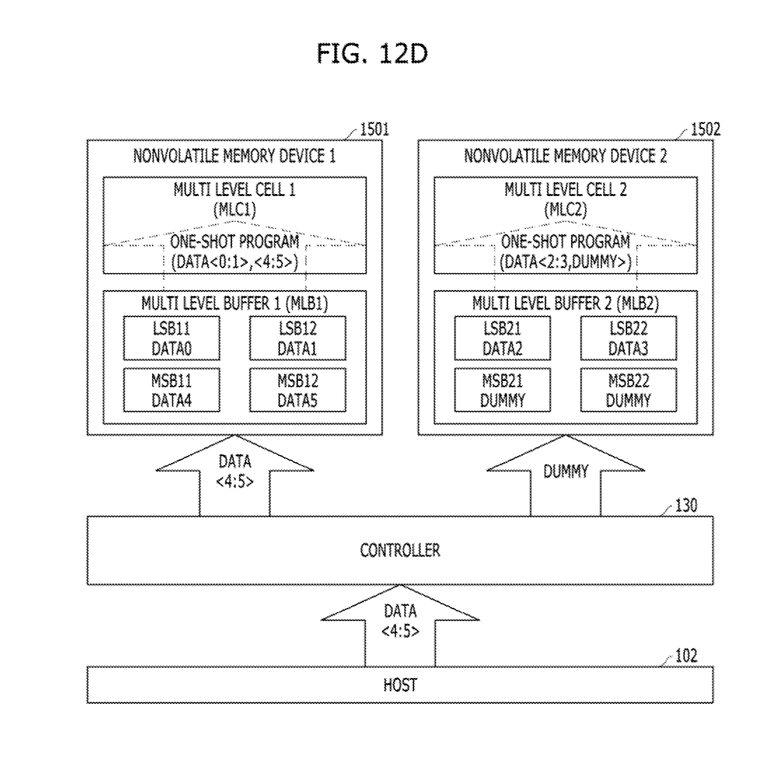

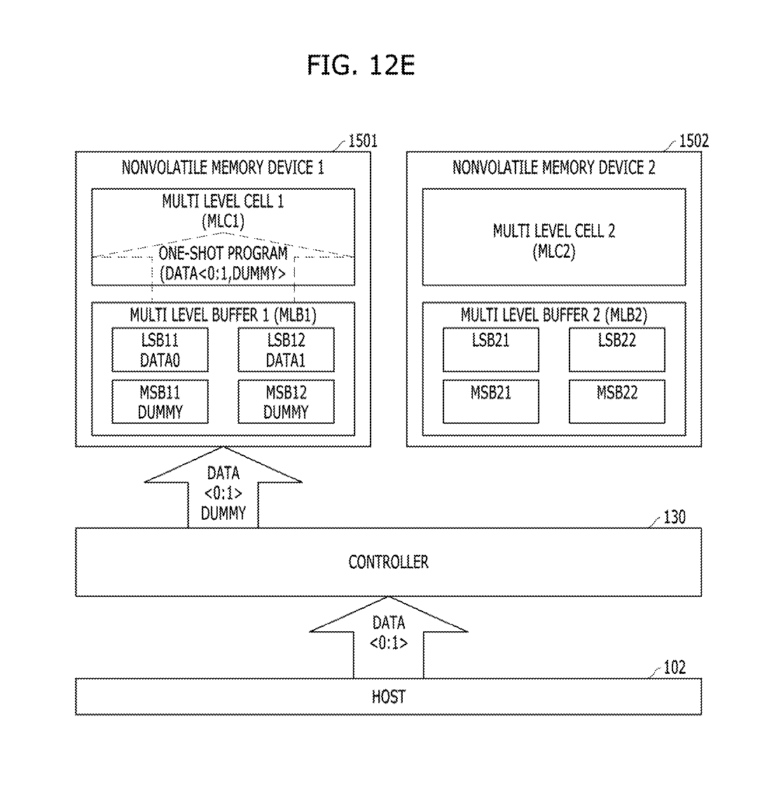

FIGS. 12A to 12E are block diagrams illustrating one-shot program operation of a memory system, according to a first embodiment of the present invention.

Referring to FIGS. 12A to 12E, the configuration of a data processing system 100 including a plurality of memory devices 1501 and 1502 is shown with: reference to the configuration of the data processing system 100 of FIG. 1. For reference, FIGS. 12A to 12E exemplarily show two nonvolatile memory devices as the plurality of memory devices 1501 and 1502. It is noted that, in practice, a larger number of nonvolatile memory devices may be included as the plurality of memory devices 1501 and 1502.

More specifically, the data processing system 100 shown in FIGS. 12A to 12E may include a host 102 and a memory system 110. Furthermore, the memory system 110 may include a controller 130, the first memory device 1501, and the second memory device 1502.

The memory systems 110 of FIGS. 12A to 12E may have the same configuration. In order to describe a change of the operation of the memory system 110, the memory system 110 has been divided and shown in FIGS. 12A to 12E.

A configuration of the memory system 110, according to a first embodiment of the present invention, is described below with reference to FIG. 12A.

The first memory device 1501 may include a first Multi-level cell memory region MLC1 and a first multi-level buffer MLB1.

The first multi-level cell memory region MLC1 may indicate a memory region including a plurality of memory cells each of which is capable of storing a plurality of bit data in an array form, such as the array shown in FIG. 3. For example, the first multi-level cell memory region MLC1 may indicate a core region for storing data within the first memory device 1501, and may be considered to include all of the plurality of memory blocks 210, 220, 230, and 240 shown in FIG. 2.

Furthermore, the first multi-level buffer MLB1 may indicate a plurality of buffers capable of temporarily storing a plurality of bit data at the same time in order to perform a one-shot program in the first multi-level cell memory region MLC1. The first multi-level buffer MLB1 may be considered to include all of the plurality of page buffers 322, 324, and 326 shown in FIG. 3. In this case, the one-shot program means an operation for programming a plurality of bit data in the first multi-level cell memory region MLC1 through a single program operation. Accordingly, as shown in FIG. 12A assuming that the first multi-level cell memory region MLC1 includes a memory cell capable of storing data of 2 bits at the same time, the first multi-level buffer MLB1 may include first lower level buffers LSB11 and LSB12 and first higher level buffers MSB11 and MSB12.

The second memory device 1502 may include a second multi-level cell memory region MLC2 and a second multi-level buffer MLB2.

The second multi-level cell memory region MLC2 may indicate a region, including memory cells each of which is capable of storing a plurality of bit data in an array form, such as the array shown in FIG. 3. For example, the second multi-level cell memory region MLC2 may indicate a core region for storing data within the second memory device 1502, and may include all of the plurality of memory blocks 210, 220, 230, and 240 shown in FIG. 2.

Furthermore, the second multi-level buffer MLB2 may indicate a plurality of buffers capable of temporarily storing a plurality of bit data at the same time in order to perform a one-shot program in the second multi-level cell memory region MLC2. The second multi-level buffer MLB2 may include all of the plurality of page buffers 322, 324, and 326 shown in FIG. 3. In this case, the one-shot program means an operation for programming a plurality of bit data in the second multi-level cell memory region MLC2 through a single program operation. Accordingly, as shown in FIG. 12A, if the second multi-level cell memory region MLC2 includes a memory cell capable of storing data of 2 bits at the same time the second multi-level buffer MLB2 may include second lower level buffers LSB21 and LSB22 and second higher level buffers MSB21 and MSB22.

The controller 130 may control the first and second memory devices 1501 and 1502, as may be needed, in response to a request from the host 102, as described above with reference to FIG. 1.

A detailed description of an operation of the controller 130 controlling the first and second memory devices 1501 and 1502 is provided herein with reference to FIGS. 12A to 12E.

First, referring to FIG. 12A, the controller 130 may store input data DATA<0:3>, received from the host 102, in the first multi-level buffer MLB1 of the first memory device 1501 and the second multi-level buffer MLB2 of the second memory device 1502 in an interleaving way.

For example, as shown in FIG. 12A, when the four input data DATA<0:3> is inputted from the host 102 to the memory system 110, the controller 130 may control the first and second memory devices 1501 and 1502 to buffer the four input data DATA<0:3> in an alternating manner in the order of input. For example, as, shown in FIG. 12A, the first two data DATA<0:1> may be transferred and buffered in the first multi-level buffer MLB1 of the first memory device 1501, and the remaining two data DATA<2:3> may be transferred and buffered in the second multi-level buffer MLB2 of the second memory device 1502.

For example, the drawings exemplarily show that each of the first and second multi-level buffers MLB1 and MLB2 are configured to buffer two data at once, so that the first two data DATA<0:1> may be buffered in the first multi-level buffer MLB1 and the immediately following two data DATA<2:3> may be buffered in the second multi-level buffer MLB2. However, it is noted that the invention may not be limited in this way and it is possible to buffer all the input data in a different interleaving way. For example, the data may be alternately buffered into the first and second buffers one by one.

The controller 130 may control the inputting of the data into the buffers based on a “preset size.” The controller 130 may control each of the first memory device 1501 and the second memory device 1502 in a different way.

The “preset size” may indicate a size for buffering data in each of the first and second multi-level buffers MLB1 and MLB2 at a unit level.

For example, it may be assumed, as shown in the embodiment of FIG. 12A, that the first multi-level buffer MLB1 may include the first lower level buffers LSB11 and LSB12 and the first higher level buffers MSB11 and MSB12 and that the second multi-level buffer MLB2 may include the second lower level buffers LSB21 and LSB22 and the second higher level buffers MSB21 and MSB22. In this case, buffering data in an interleaving manner in each of the first and the second multi-level buffers MLB1 and MLB2 at a unit level may result in buffering data in the first lower level buffers LSB11 and LSBI2 and the second lower level buffers LSB21 and LSB22 but not in the first higher level buffers MSB11 and MSB12 and the second higher lever buffers MSB21 and MSB22.

Accordingly, as shown in FIG. 12A, the state in which the 0-th and the first input data DATA<0:1> of the four input data DATA<0:3> have been buffered in the first lower level buffers LSB11 and LSB12 of the first multi-level buffer MLB1 and the second and the third input data DATA<2:3> thereof have been buffered in the second lower level buffers LSB21 and LSB22 of the second multi-level buffer MLB2 may be considered to be the state in which the data have been buffered in each of the first multi-level buffer MLB1 and the second multi-level buffer MLB2 at unit level. For example, the state in which the four input data DATA<0:3> have been inputted as shown in FIG. 12A may be considered to be the state in which data having the “preset size” have been inputted.

As described above, the controller 130 may control the first memory device 1501 and the second memory device 1502 in a different way, depending on whether subsequent input data may be present or not, in the state in which the four input data DATA<0:3> having the “preset size” have been inputted, as in FIG. 12A.

First, from FIG. 12B, it may be seen how the controller 130 may control the first memory device 1501 and the second memory device 1502, if data to be inputted is no longer present (END) after the four input data DATA<0:3> having the “preset size” are inputted as in FIG. 12A.

More specifically, in FIG. 12B, it is assumed that a total number of the input data DATA<0:3> is four and the input data DATA<0:3> has the same size as the “preset size”. Accordingly, in this example, at the time of completion of buffering the input data DATA<0:3>, all of the input data DATA<0:3> have been buffered in the first lower level buffers LSB11 and LSB12 and the second lower level buffers LSB21 and LSB22 only.

In this state, the controller 130 may move data buffered in the second lower level buffers LSB21 and LSB22 of the second memory device 1502, that is, the second and the third data DATA<2:3>, to the first higher level buffers MSB11 and MSB12 of the first memory device 1501 and then perform a one-shot program on the first memory device 1501 only.

In this case, a method of moving the data buffered in the second lower level buffers LSB21 and LSB22 of the second memory device 1502, that is, the second and the third data DATA<2:3> to the first higher level buffers MSB11 and MSB12 of the first memory device 1501 may include the following two methods.

In a first method, the second and the third data DATA<2:3> which are stored temporarily in the memory 144 of the controller 130 in the process of buffering the second and the third data DATA<2:3> in the second lower level buffers LSB21 and LSB22 of the second memory device 1502 as in FIG. 12B may remain intact without being deleted. Thereafter, the second and the third data DATA<2:3> may be directly moved from the memory 144 to the first higher level buffers MSB11 and MSB12 of the first memory device 1501 when the second and the third data DATA<2:3> needs to be moved.

In a second method, unlike in FIG. 12B the second and the third data DATA<2:3> buffered in the second lower level buffers LSB21 and LSB22 of the second memory device 1502 may be read again when they need to be moved, and the read second and third data DATA<2:3> may be moved to the first higher level buffers MSB11 and MSB12 of the first memory device 1501.

After the operation for moving the second and the third data DATA<2:3> is terminated by either the first or second aforementioned methods, the second and the third data DATA<2:3> buffered in the second lower level buffers LSB21 and LSB22 of the second memory device 1502 may be deleted.

The 0-th and the first data DATA<0:1> have already been buffered in the first lower level buffers LSB11 and LSB12 of the first memory device 1501. Accordingly, when the second and the third data DATA<2:3> are buffered in the first higher level buffers MSB11 and MSB12 through the operation shown in FIG. 12B, a one-shot program may be performed in the state in which the input data DATA<0:3> have been fully buffered in the first multi-level buffer MLB1 of the first memory device 1501 without an empty space.

If, in the state of FIG. 12A, a one-shot program is performed on each of the first and the second memory devices 1501 and 1502 without performing the operation shown in FIG. 12B, dummy data (not shown) should have been buffered in the first higher level buffers MSB11 and MSB12, that is, the empty spaces in the first multi-level buffer MLB1 of the first memory device 1501, and the second higher level buffers MSB21 and MSB22, that is, empty spaces in the second multi-level buffer MLB2 of the second memory device 1502, and the one-shot program should have been performed on each of the first and the second memory devices 1501 and 1502.

In contrast, as shown in FIG. 12B, the controller 130 may move the second and the third data DATA<2:3>, buffered in the second lower level buffers LSB21 and LSB22 of the second memory device 1502, to the first higher level buffers MSB11 and MSB12 of the first memory device 1501, and thus an empty space may not be present in the first multi-level buffer MLB1 of the first memory device 1501. Accordingly, the one-shot program may be performed on the first memory device 1501 without a process of separately buffering dummy data in the first multi-level buffer MLB1. Furthermore, the one-shot program does not need to be performed on the second memory device 1502 because no data have been buffered in the second multi-level buffer MLB2 of the second memory device 1502.

Accordingly as shown in FIG. 12B, the controller 130 may buffer the input data DATA<0:3> having a size of four that is equal to the preset size in the first memory device 1501 only and then perform the one-shot program operation on the first memory device 1501 only.

However, it is noted that the invention may not be limited in this way. For example, assuming that the controller 130 may buffer the input data DATA<0:3> in an interleaving way in which some of the input data may be buffered in the second memory device 1502 and the remaining input data may be buffered in the first memory device 1501, the controller 130 may buffer the input data DATA<0:3> having a size equal to the preset size in the second memory device 1502 only and perform the one-shot program operation on the second memory device 1502 (not shown).

In summary, according to an embodiment of the invention, the controller 130 may buffer the input data DATA<0:3> in the first multi-level buffer MLB1 of the first memory device 1501 and the second multi-level buffer MLB2 of the second memory device 1502 in an interleaving way. More specifically, the controller may first check the size of the input data and if the size of the input data DATA<0:3> has a “preset size”, the controller 130 may then buffer ail of the input data DATA<0:3> in the first multi-level buffer MLB1 of the first memory device 1501 only in order to perform a one-shot program operation on the first memory device 1501 only. Alternatively, the controller 130 may buffer all of the input data DATA<0:3> having a size equal to the “Preset size” in the second multi-level buffer MLB2 of the second memory device 1502 only in order to perform a one-shot program operation on the second memory device 1502 only.

FIG. 12C, illustrates how the controller 130 may control the first and second memory devices 1501 and 1502 when four input data DATA<4:7> are additionally inputted after the four input data DATA<0:3> having a size equal to the preset size are inputted as in FIG. 12A.

More specifically, in FIG. 12C, t is assumed that the total number of the input data DATA<0:7> is 8 which is greater than the preset size which is four. Accordingly, buffering the input data in an interleaving way means that the input data DATA<0:7> may be first buffered in the first lower level buffers LSB11 and LSB12 and the second lower level buffers LSB21 and LSB22 and then buffered in the first higher level buffers MSB11 and MSB12 and the second higher level buffers MSB21 and MSB22.

For example, the controller 130 may fully buffer the input data DATA<0:7> in the first multi-level buffer MLB1 of the first memory device 1501 and the second multi-level buffer MLB2 of the second memory device 1502 without leaving any empty space.

Accordingly, after all of the input data DATA<0:7> may be buffered, the controller 130 may perform a one-shot program operation on each of the first and second memory devices 1501 and 1502.

FIG. 12D illustrates how the controller 130 may control the first and second memory devices 1501 and 1502 when two input data DATA<4:5> are additionally inputted after the four input data DATA<0:3> having the preset size of four are inputted as in FIGS. 12A.

More specifically, in FIG. 12D, it is assumed that a total number of the input data DATA<0:5> may be 6 which is greater than the preset size of four and is not an integer multiple of the preset size. Accordingly, buffering the input data in an interleaving way means that the input data DATA<0:5> may be first buffered in the first lower level buffers LSB11 and LSB12 and the second lower level buffers LSB21 and LSB22 and then buffered only in the first higher level buffers MSB11 and MSB12. In this case, the input data DATA<0:5> may not be buffered in the second higher level buffers MSB21 and MSB22 because there is only six input data which means that all of the input data DATA<0:5> have been buffered in the first and second lower level buffers LSB11, LSB12 and LSB21, LSB22 and the first higher level buffers MSB11, MSB12.

Hence, in this example, where the total number of input data is 6 and the preset size is four, the controller 130 is able to fully buffer the input data DATA<0:5> in the first multi-level buffer MLB1 of the first memory device 1501 without leaving any empty space, but is unable to fully buffer the second multi-level buffer MLB2 of the second memory device 1502.

Furthermore, since the input data DATA<0:5> have a size that is greater than the preset size it may not be possible to move all the data, buffered in the second multi-level buffer MLB2 of the second memory device 1502, to the first multi-level buffer MLB1 of the first memory device 1501 as was done in the example of FIG. 12B.

Accordingly, the controller 130 may need to buffer dummy data DUMMY in the empty spaces of the second multi-level buffer MLB2 of the second memory device 1502 before performing the one-shot program operation on the second memory device 1502. For example, the controller 130 may buffer the dummy data DUMMY in the second higher level buffers MSB21 and MSB22 included in the second multi-level buffer MLB2 of the second memory device 1502 and then perform the one-shot program operation on the second memory device 1502.

In this example with input data DATA<0:5> all input data have been buffered in the first and second multi-level buffers MLB1 and MLB2 without leaving any empty space in the multi-level buffer MLB1 of the first memory device 1501. Accordingly, the controller 130 may perform the one-shot program operation on the first memory device 1501 after all of the input data DATA<0:5> have been buffered.

In FIG. 12E, it is assumed that input data DATA<0:1> may have a size smaller than the preset size of four, unlike in the case where the input data DATA<0:3> have the preset size of four as in FIG. 12A. For example, in FIG. 12E, a total number of the input data DATA<0:1> may be 2, i.e., smaller than the preset size of four. Accordingly, in the example of FIG. 12E, at the time of completion of buffering the input data DATA<0:1>, all of the input data DATA<0:1> have been buffered in the first lower level buffers LSB11 and LSB12 only.

Hence in the example of FIG. 12E, since all of the input data DATA<0:1> has been fully buffered in the first lower level buffers LSB11 and LSB12 of the first memory device 1501, the input data DATA<0:1> may not be buffered in the second lower level buffers LSB21 and LSB22 of the second memory device 1502, the first higher level buffers MSB11 and MSB12 of the first memory device 1501 and the second higher level buffers MSB21 and MSB22 of the second memory device 1502.

Accordingly, in this case, the one-shot program operation does not need to be performed on the second memory device 1502 because the second multi-level buffer MLB2 of the second memory device 1502 maintains a fully empty space.

However, dummy data DUMMY may need to be buffered in the empty first higher level buffers MSB11 and MSB12 of the first multi-level buffer MLB1 of the first memory device 1501 before the one-shot program operation may be performed on the first memory device 1501 because the input data DATA<0:1> has been buffered in the first lower level buffers LSB11 and LSB12 of the first multi-level buffer MLB1 of the first memory device 1501 only. For example, the controller 130 may buffer the dummy data DUMMY in the first higher level buffers MSB11 and MSB12 included in the first multi-level buffer MLB1 of the first memory device 1501 and then perform the one-shot program operation on the first memory device 1501.

FIGS, 13A to 13G are block diagrams illustrating a one-shot program operation performed by a memory system, according to a second embodiment of the present invention.

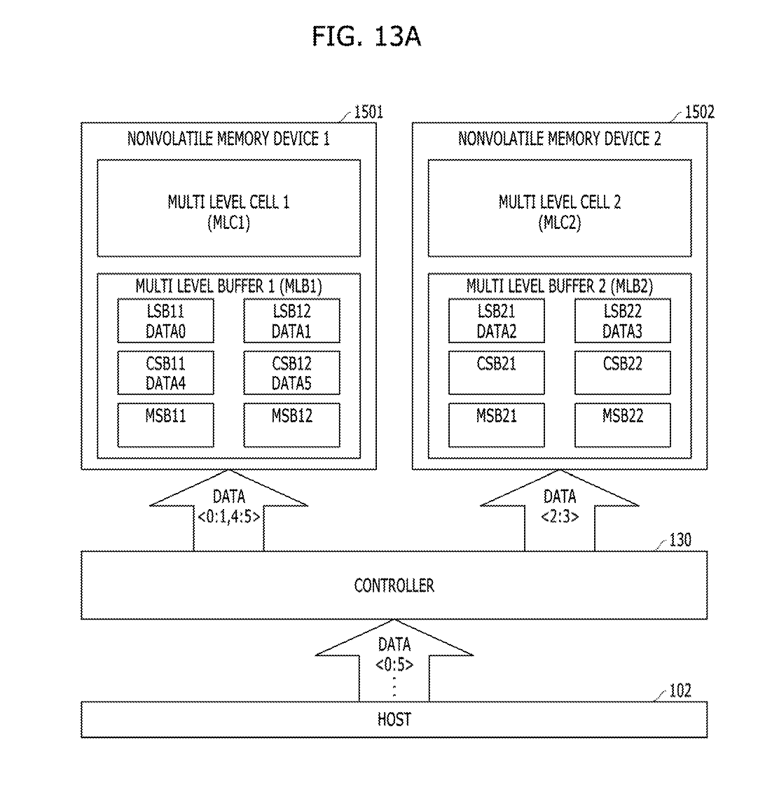

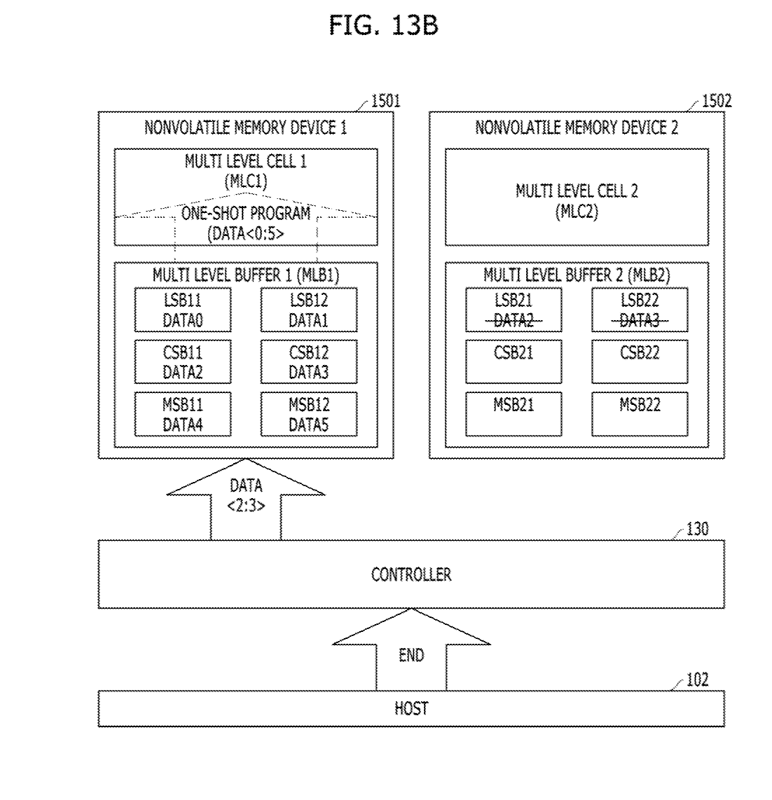

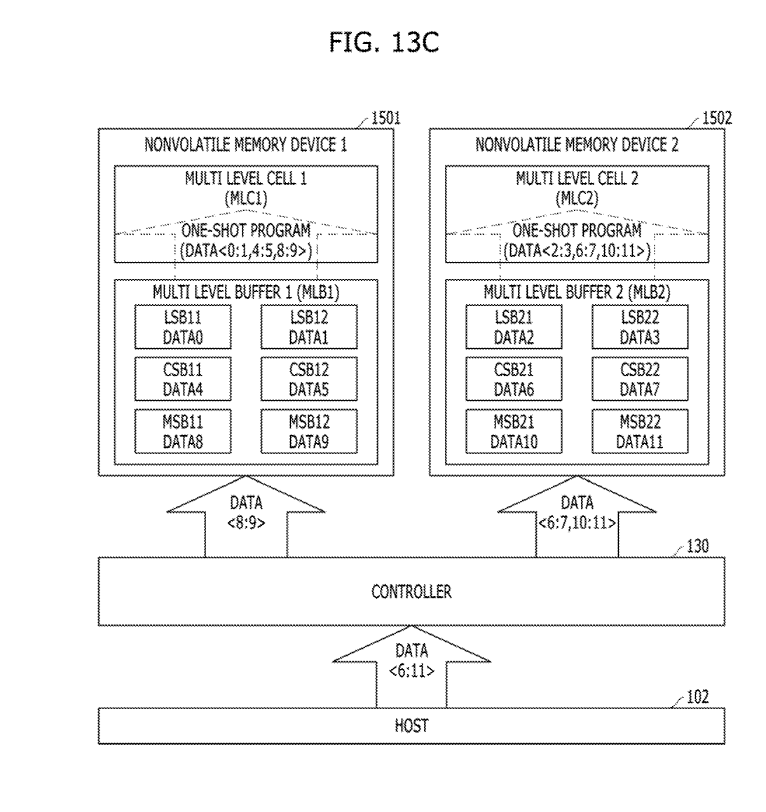

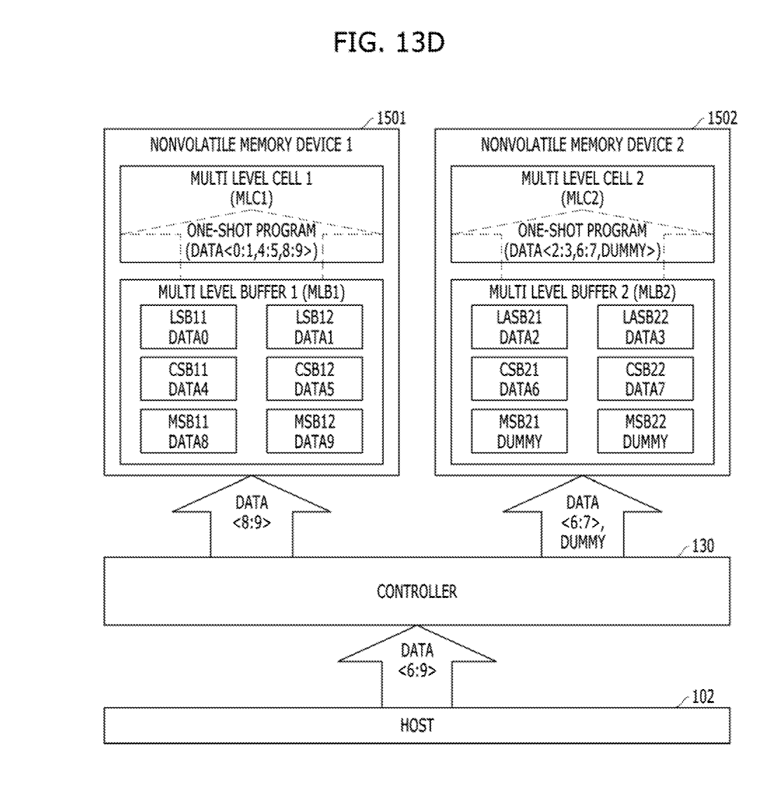

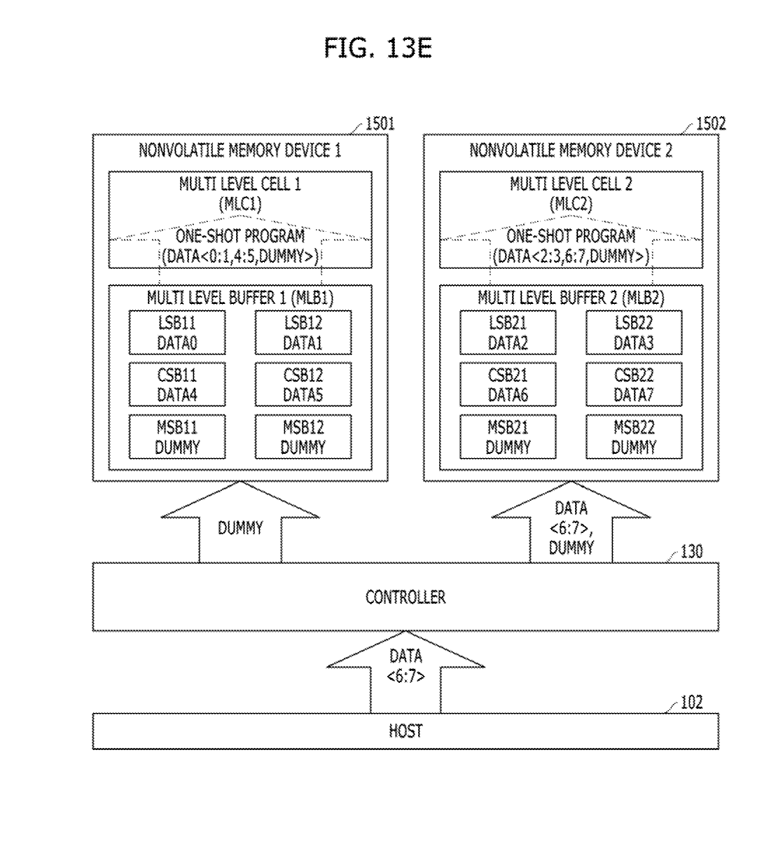

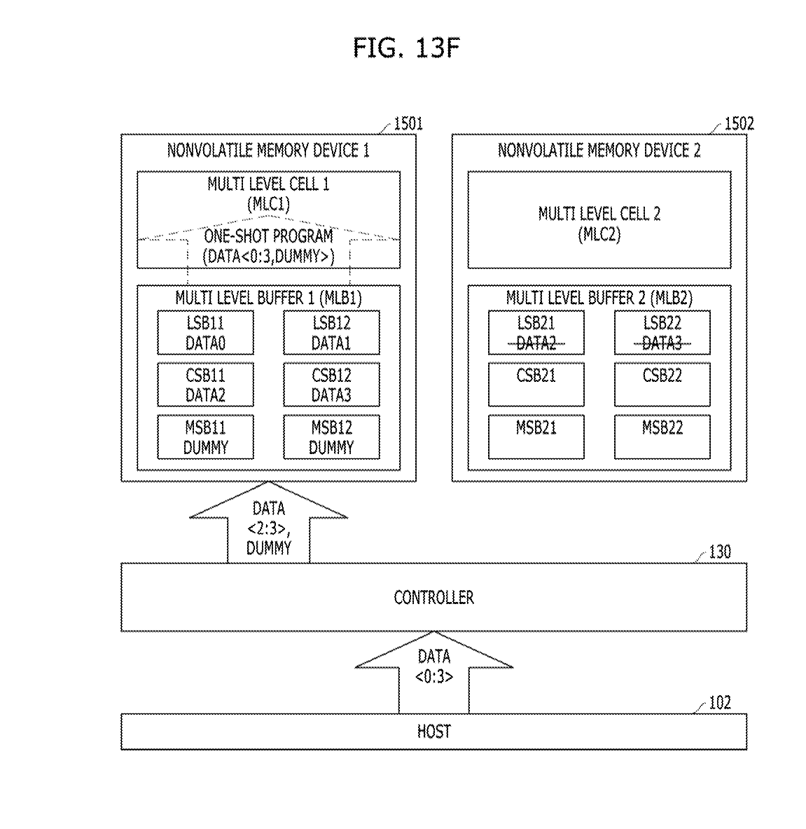

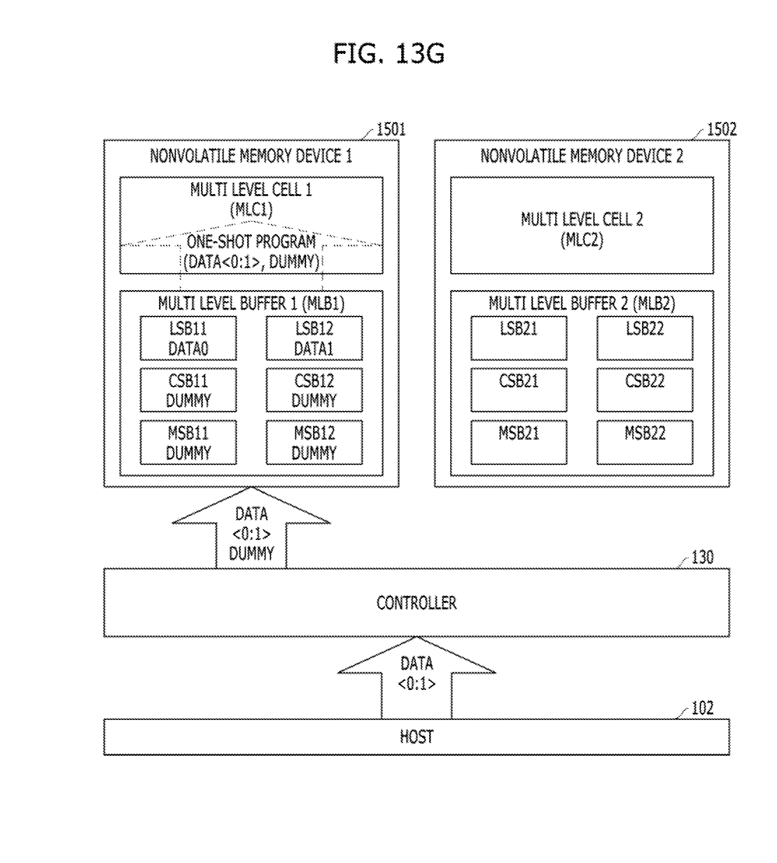

Referring to FIGS. 13A to 13G, the configuration of a data processing system 100 including a plurality of memory devices 1501 and 1502 is shown with reference to the configuration of the data processing system 100 of FIG. 1. For reference, FIGS. 13A to 13G exemplarily show two nonvolatile memory devices as the plurality of memory devices 1501 and 1502. It is noted that, in practice, a larger number of nonvolatile memory devices may be included as the plurality of memory devices 1501 and 1502.

More specifically, the data processing system 100 shown in FIGS. 13A to 13G may include a host 102 and a memory system 110. Furthermore, the memory system 110 may include a controller 130, the first memory device 1501, and the second memory device 1502.

The memory systems 110 of FIGS. 13A to 13G may have the same configuration. In order to describe a change of the operation of the memory system 110, the memory system 110 has been divided and shown in FIGS. 13A to 13G.

Accordingly, the configuration of the memory system 110 according to the second embodiment of the present invention described below with reference to FIG. 13A.

The first memory device 1501 may include a first multi-level cell memory region MLC1 and a first multi-level buffer MLB1.

The first multi-level cell memory region MLC1 may indicate a region, including a plurality of memory cells each of which is capable of storing a plurality of bit data in an array form, such as the array shown in FIG. 3. For example, the first multi-level cell memory region MLC1 may indicate a core region for storing data within the first memory device 1501, and may include all of the plurality of memory blocks 210, 220, 230, and 240 shown in FIG. 2.

Furthermore, the first multi-level buffer MLB1 may indicate a plurality of buffers capable of temporarily storing a plurality of bit data at the same time in order to perform a one-shot program in the first multi-level cell memory region MLC1. The first multi-level buffer MLB1 may include all of the plurality of page buffers 322, 324, and 326 shown in FIG. 3. In this case, a one-shot program may mean an operation for programming a plurality of bit data in the first multi-level cell memory region MLC1 through a single program operation. Accordingly, as shown in FIG. 13A, assuming that the first multi-level cell memory region MLC1 includes a memory cell capable of storing data of 3 bits at the same time, the first multi-level buffer MLB1 may include first lower level buffers LSB11 and LSBI2, first middle level buffers CSB11 and CSB12, and first higher level buffers MSB11 and MSB12.

The second memory device 1502 may include a second multi-level cell memory region MLC2 and a second multi-level buffer MLB2.

The second multi-level cell memory region MLC2 may indicate a region, including memory cells each of which is capable of storing a plurality of bit data in an array form, such as the array shown in FIG. 3. For example, the second multi-level cell memory region MLC2 may indicate a core region for storing data within the second memory device 1502, and may include all of the plurality of memory blocks 210, 220, 230, and 240 shown n FIG. 2.

Furthermore, the second multi-level buffer MLB2 may indicate a plurality of buffers capable of temporarily storing a plurality of bit data at the same time in order to perform a one-shot program in the second multi-level cell memory region MLC2. The second multi-level buffer MLB2 may include all of the plurality of page buffers 322, 324, and 326 shown in FIG. 3. In this case, the one-shot program may mean an operation for programming a plurality of bit data in the second multi-level cell memory region MLC2 through a one program operation. Accordingly, as shown in FIG. 13A, if the second multi-level cell memory region MLC2 includes a memory cell capable of storing data of 3 bits at the same time, the second multi-level buffer MLB2 may include second lower level buffers LSB21 and LSB22, second middle level buffers CSB21 and CSB22, and second higher level buffers MSB21 and MSB22.

The controller 130 may control the first and the second memory devices 1501 and 1502 in response to a request from the host 102 as described above with reference to FIG. 1.

A detailed operation of the controller 130 regarding how the controller 130 may control the first and second memory devices 1501 and 1502, according to a second embodiment of the invention is now provided with reference to FIGS. 13A to 13G.

First, referring to FIG. 13A, the controller 30 may store input data DATA<0:5>, received from the host 102, in the first lower level buffers LSB11 and LSB12 of the first multi-level buffer MLB1 of the first memory device 1501, the second lower level buffers of the second multi-level buffer MLB2 of the second memory device 1502, and the first middle level buffers CSB11 and CSB12 of the first memory device 1501 in an interleaving way.

For example, as shown in FIG. 13A, when the six input data DATA<0:5> is inputted from the host 102 to the memory system 110, the controller 130 may control the first memory device 1501 and the second memory device 1502 so that they alternately may buffer the six input data DATA<0:5> in the order of input in the first and the second multi-level cell memory regions MCL1 and MCL2. For example, as shown in FIG. 13A, the first 2 data DATA<0:1> may be transferred and buffered in the first multi-level buffer MLB1 of the first memory device 1501, the second 2 data DATA<2:3> may be transferred and buffered in the second multi-level buffer MLB2 of the second memory device 1502, and the third 2 data DATA<4:5> may be transferred and buffered in the first middle level buffers CSB11 and CSB12 of the first memory device 1501.

For example, since the first and the second multi-level buffers MLB1 and MLB2 are configured to buffer every two data at once, the first 2 data DATA<0:1> may be buffered in the first multi-level buffer MLB1, the second 2 data DATA<2:3> may be buffered in the second multi-level buffer MLB2, and the third 2 data DATA<4:5> may be buffered in the first multi-level buffer MLB1 again. However, it is noted that the invention may not be limited in this way and it is possible to buffer all the input data in another interleaving way. For example the data may be alternately between the first and second multi level buffer one by one.

The controller 130 may control the inputting of the input data according to a preset size in an interleaving manner between the first and second multi-level buffers MLB1 and MLB2. The controller 130 control each of the first memory device 1501 and the second memory device 1502 in a different way.

In the example of FIG. 13A, the preset size may correspond to one half of the sum of the sizes of the first and the second multi-level buffers MLB1 and MLB2.

For example, it may be assumed that the first multi-level buffer MLB1 may include the first lower level buffers LSB11 and LSB12, the first middle level buffers CSB11 and CSB12, and the first higher level buffers MSB11 and MSB12 and the second multi-level buffer MLB2 may include the second lower level buffers LSB21 and LSB22, the second middle level buffers CSB21 and CSB22 and the second higher level buffers MSB21 and MSB22. In this case, to buffer data according to a preset size corresponding to a one half of the sum of the sues of the first and the second multi-level buffers MLB1 and MLB2 means that data may be buffered in the first lower level buffers LSB11 and LSB12, the second lower level buffers LSB21 and LSB22, and the first middle level buffers CSB11 and CSB12, but not in the second middle level buffers CSB21 and CSB22, the first higher level buffers MSB11 and MSB12, and the second higher level buffers MSB21 and MSB22.

Accordingly, as shown in FIG. 13A, the state in which the 0-th and the first input data DATA<0:1> of the six input data DATA<0:5> have been buffered in the first lower level buffers LSB11 and LSB12 of the first multi-level buffer MLB1, the second and the third input data DATA<2:3> thereof have been buffered in the second lower level buffers LSB21 and LSB22 of the second multi-level buffer MLB2, and the fourth and the fifth input data DATA<4:5> thereof have been buffered in the first middle level buffers CSB11 and CSB12 of the first multi-level buffer MLB1 may be considered to be the state in which data having the size corresponding to one half of the sum of the size of the first multi-level buffer MLB1 and the size of the second multi-level buffer MLB2 have been buffered. For example, the state in which the six input data DATA<0:5> have been inputted as shown in FIG. 13A may be considered to be the state in which data having the “preset size” have been inputted.

As described above, the controller 130 may control the first and second memory devices 1501 and 1502 in a different way, depending on whether subsequent input data may be present or not, fin the state in which the six input data DATA<0:5> having the preset size have been inputted, as in FIG. 13A.

FIG. 13B, illustrates how the controller 130 may control the first and the second memory devices 1501 and 1502, if data to be inputted is no longer present (END) after the six input data DATA<0:5> having the preset size are inputted as in FIG. 13A.

More specifically, in FIG. 13B, it is assumed that the total number of the input data DATA<0:5> may be six and the input data DATA<0:5> may have the same size as the “preset size”. Accordingly, all of the input data DATA<0:5> may have been buffered at the time of completion of buffering the input data DATA<0:5> in the first lower level buffers LSB11 and LSB12, the second lower level buffers LSB21 and LSB22, and the first middle level buffers CSB11 and CSB12 only.

In this state, the controller 130 may move data buffered in the to first middle level buffers CSB11 and CSB12 of the first memory device 1501, that is, the fourth and the fifth data DATA<4:5>, to the first higher level buffers MSB11 and MSB12 of the first memory device 1501, move data buffered in the second lower level buffers LSB21 and LSB22 of the second memory device 1502, that is, the second and the third data DATA<2:3>, to the first middle level buffers CSB11 and CSB12 of the first memory device 1501, and then perform a one-shot program on the first memory device 1501 only.

In this case, if the data buffered in the second lower level buffers LSB21 and LSB22 of the second memory device 1502, that is, the second and the third data DATA<2:3>, are directly moved to the first higher level buffers MSB11 and MSB12 of the first memory device 1501 as in FIG. 13A because the first higher level buffers MSB11 and MSB12 of the first memory device 1501 may be empty spaces, the one-shot program operation for the first memory device 1501 may become complicated.

The reason for this is that if the second and the third data DATA<2:3> buffered in the second lower level buffers LSB21 and LSB22 of the second memory device 1502 may be directly moved to the first higher level buffers MSB11 and MSB12 of the first memory device 1501, the 0-th and the first data DATA<0:1> may be subsequently buffered in the first lower level buffers LSB11 and LSB12 of the first memory device 1501, the fourth and the fifth data DATA<4:5> may be buffered in the first middle level buffers CSB11 and CSB12, and the second and the third data DATA<2:3> may be buffered in the first higher level buffers MSB11 and MSB12. In this state, if the common one-shot program operation were to be performed on the first memory device 1501, the data stored in the first middle level buffers CSB11 and CSB12 and the first higher level buffers MSB11 and MSB12 would be mixed.

For this reason, as in FIG. 13B, a method of moving the fourth and the fifth data DATA<4:5> buffered in the first middle level buffers CSB11 and CSB12 of the first memory device 1501, to the first higher level buffers MSB11 and MSB12 of the first memory device 1501 and moving the second and the third data DATA<2:3>, buffered in the second lower level buffers LSB21 and LSB22 of the second memory device 1502, to the first middle level buffers CSB11 and CSB12 of the first memory device 1501 before moving the second and the third data DATA<2:3>, buffered in the second lower level buffers LSB21 and LSB22 of the second memory device 1502, to the first memory device 1501 may be used.

In this case, the method of moving the data buffered in the second lower level buffers LSB21 and LSB22 of the second memory device 1502, that is, the second and the third data DATA<2:3>, to the first middle level buffers CSB11 and CSB12 of the first memory device 1501 may include the following two methods.

In a first method, the second and the third data DATA<2:3> which are stored temporarily according to the interleaving buffering process in the second lower level buffers LSB21 and LSB22 of the second memory device 1502 as in FIG. 13B may remain intact without being deleted. Thereafter, the second and the third data DATA<2:3> may be directly moved from the memory 144 to the first middle level buffers CSB11 and CSB12 of the first memory device 1501 at a time when the second and the third data DATA<2:3> needs to be moved.

In a second method, unlike in FIG. 13B, the second and the third data DATA<2:3> buffered in the second lower level buffers LSB21 and LSB22 of the second memory device 1502 may be read again when they need to be moved, and the read second and third data DATA<2:3> may be moved to the first middle level buffers CSB11 and CSB12 of the first memory device 1501.

After the operation for moving the second and the third data DATA<2:3> is completed using either of the above mentioned first or second method, the second and the third data DATA<2:3> buffered in the second lower level buffers LSB21 and LSB22 of the second memory device 1502 may be deleted.

In the example of FIG. 13B, the 0-th and the first data DATA<0:1> have already been buffered in the first lower level buffers LSB11 and LSB12 of the first memory device 1501, and the fourth and the fifth data DATA<4:5> have already been buffered in the first higher level buffers MSB11 and MSB12 of the first memory device 1501. Accordingly, if the second and the third data DATA<2:3> is buffered in the first middle level buffers CSB11 and CSB12, a one-shot program may then be performed in the state in which the input data DATA<0:5> have been fully buffered, in the correct order, in the first multi-level buffer MLB1 of the first memory device 1501 without an empty space.

If, in the state of FIG. 13B, a one-shot program is performed on each of the first memory device 1501 and the second memory device 1502 without performing the operation shown in FIG. 13B, dummy data (not shown) should have been buffered in the first higher level buffers MSB11 and MSB12 that is empty spaces in the first multi-level buffer MLB1 of the first memory device 1501, and the second middle level buffers CSB21 and CSB22 and the second higher level buffers MSB21 and MSB22, that is, empty spaces in the second multi-level buffer MLB2 of the second memory device 1502, and the one-shot program should have been performed on each of the first memory device 1501 and the second memory device 1502.

In contrast, as shown in FIG. 13B, the controller 130 may move the second and the third data DATA<2:3>, buffered in the second lower level buffers LSB21 and LSB22 of the second memory device 1502, to the first middle level buffers CSB11 and CSB12 of the first memory device 1501, and thus an empty space may not be present in the first multi-level buffer MLB1 of the first memory device 1501. Accordingly, the one-shot program may be performed on the first memory device 1501 without a process of separately buffering dummy data in the first multi-level buffer MLB1. Furthermore, the one-shot program does not need to be performed on the second memory device 1502 because no data remain buffered in the second multi-level buffer MLB2 of the second memory device 1502.

For reference, as shown in FIG. 13A, the controller 130 has buffered the input data DATA<0:5> in an interleaving way so that some of the input data may be buffered in the first memory device 1501 and the remaining input data may be buffered in the second memory device 1502. Accordingly, as shown in FIG. 13B, the controller 130 may buffer the input data DATA<0:5> having the preset size in the first memory device 1501 only and then perform the one-shot program operation on the first memory device 1501. However, it is noted that the invention may not be limited in this way. Assuming that the controller 130 may buffer the input data DATA<0:5> in an interleaving way in which some of the input data may be buffered in the second memory device 1502 and the remaining input data may be buffered in the first memory device 1501 unlike in FIG. 13A, the controller 130 may buffer the input data DATA<0:5> having the preset size in the second memory device 1502 only and perform the one-shot program operation on the second memory device 1502 unlike in FIG. 13B.

In summary, the controller 130 may buffer the input data DATA<0:5> in the first and second multi-level buffers MLB1 and MLB2 of the first and second memory devices 1501 and 1502, respectively, in an interleaving ways. If the input data DATA<0:5> has a size equal to a preset size, the controller 130 may buffer all of the input data DATA<0:5> in the first multi-level buffer MLB1 of the first memory to device 1501 only to perform the one-shot program operation on the first memory device 1501 only. Alternatively, if the input data DATA<0:5> has a size equal to a preset size the controller 130 may buffer all of the input data DATA<0:5> in the second multi-level buffer MLB2 of the second memory device 1502 only to perform a one-shot program operation on the second memory device 1502 only.

FIG. 13C illustrates how the controller 130 may control the first and the second memory devices 1501 and 1502 when six input data DATA<6:11> are additionally inputted after the six input data DATA<0:5> having the preset size are inputted as in FIG. 13A.

More specifically, in FIG. 13C, it is assumed that a total number of the input data DATA<0:11> is 12 and that the input data DATA<0:11> have a size greater than the preset size which is six. Accordingly, the input data DATA<0:11> may be buffered in the first lower level buffers LSB11 and LSB12 and the second lower level buffers LSB21 and LSB22, then buffered in the first middle level buffers CSB11 and CSB12 and the second middle level buffers CSB21 and CSB22, and then buffered in the first higher level buffers MSB11 and MSB12 and the second higher level buffers MSB21 and MSB22.

For example, the controller 130 may fully buffer the input data DATA<0:11> in the first multi-level buffer MLB1 of the first memory device 1501 and the second multi-level buffer MLB2 of the second memory device 1502 without any empty space in any of the multi-level buffers MLB1 and MLB2.

Accordingly, after all of the input data DATA<0:1> may be buffered, the controller 130 may perform a one-shot program on each of the first and the second memory devices 1501 and 1502.

FIG. 13D illustrates how the controller 130 may control the first and second memory devices 1501 and 1502 when four input data DATA<6:9> are additionally inputted after the six input data DATA<0:5> having the preset size are inputted as in FIG. 13A.

More specifically, in FIG. 13D, it is assumed that a total number of the input data DATA<0:9> may be 10 and the input data DATA<0:9> which is greater than the preset size. Accordingly, the input data DATA<0:9> may be buffered in the first lower level buffers LSB11 and LSB12 and the second lower level buffers LSB21 and LSB22, then buffered in the first middle level buffers CSB11 and CSB12 and the second middle level buffers CSB21 and CSB22, and then buffered in the first higher level buffers MSB11 and MSB12. In this case, the input data DATA<0:9> may not be buffered in the second higher level buffers MSB21 and MSB22 because all of the input data DATA<0:9> have been buffered in the first higher level buffers MSB11 and MSB12.

For example, the controller 130 is able to fully buffer the input data DATA<0:9> in the first multi-level buffer MLB1 of the first memory device 1501 without leaving any empty space, but is unable to fully buffer in the second multi-level buffer MLB2 of the second memory device 1502.

Furthermore, since the input data DATA<0:9> has a size that is to greater than the preset size of six, it may not be possible to move all the data, buffered in the second multi-level buffer MLB2 of the second memory device 1502, to the first multi-level buffer MLB1 of the first memory device 1501 as in FIG. 13B.

Accordingly, the controller 130 may need to buffer dummy data DUMMY in the empty spaces of the second multi-level buffer MLB2 of the second memory device 1502 before performing the one-shot program operation on the, second memory device 1502. For example, the controller 130 may buffer the dummy data DUMMY in the second higher level buffers MSB21 and MSB22 included in the second multi-level buffer MLB2 of the second memory device 1502 and then perform the one-shot program operation on the second memory device 1502.

In this case, it may be considered that all of the input data DATA<0:9> have been buffered in the first multi-level buffer MLB1 of the first memory device 1501 without leaving any empty space.

Accordingly, the controller 130 may perform the one-shot program operation on the first memory device 1501 after all of the input data DATA<0:9> have been buffered.

FIG. 13E illustrates how the controller 130 may control the first and second memory devices 1501 and 1502 when two input data DATA<6:7> are additionally inputted after the six input data DATA<0:5> having the preset size are inputted as in FIG. 13A.

More specifically, in FIG. 13E, a total number of the input data DATA<0:7> may be 8, i.e., a size greater than the preset size of six. Accordingly, the input data DATA<0:7> may first be buffered in the first lower level buffers LSB11 and LSB12 and the second lower level buffers LSB21 and LSB22 and then buffered in the first middle level buffers CSB11 and CSB12 and the second middle level buffers CSB21 and CSB22. In this case, the input data DATA<0:7> may not be buffered in the first higher level buffers MSB11 and MSB12 and the second higher level buffers MSB21 and MSB22 because all of the input data DATA<0:7> have been buffered in the second middle level buffers CSB21 and CSB22.

For example the controller 130 may be unable to fully buffer the input data DATA<0:7> in the first multi-level buffer MLB1 of the first memory device 1501 and the second multi-level buffer MLB2 of the second memory device 1502 without leaving any empty space.

Furthermore, since the input data DATA<0:7> have a size that is greater than the preset size, the controller 130 may be unable to move all the data, buffered in the second multi-level buffer MLB2 of the second memory device 1502, to the first multi-level buffer MLB1 o the first memory device 1501 as in FIG. 13B.

Accordingly, the controller 130 may need to buffer dummy data DUMMY in the empty spaces of the first multi-level buffer MLB1 of the first memory device 1501 before performing the one-shot program operation on the first memory device 1501. For example, the controller 130 may buffer the dummy data DUMMY in the first higher level buffers MSB11 and MSB12 of the first multi-level buffer MLB1 of the first memory device 1501 and then perform the one-shot program operation on the first memory device 1501.

Likewise, the controller 130 may need to buffer dummy data DUMMY in the empty spaces of the second multi-level buffer MLB2 of the second memory device 1502 before performing the one-shot program operation on the second memory device 1502. For example, the controller 130 may buffer the dummy data DUMMY in the second higher level buffers MSB21 and MSB22 of the second multi-level buffer MLB2 of the second memory device 1502 and then perform the one-shot program operation on the second memory device 1502.

In FIG. 13F, it is assumed that input data DATA<0:3> may have a size that is smaller than the preset size, unlike in the case where the input data DATA<0:5> had a size equal to the preset size as in FIG. 13A. For example, in FIG. 13F, a total number of the input data DATA<0:3> may be 4, i.e., smaller than the preset size of six.

Accordingly, at the time of completion of buffering the input data DATA<0:3>, all of the input data DATA<0:3> may have been buffered in the first lower level buffers LSB11 and LSB12 and the second lower level buffers LSB21 and LSB22 only of the first and second multi-level buffers MLB1 and MLB2, respectively.

Hence in the example of FIG. 13F, the controller 130 may be unable to fully buffer the input data DATA<0:3> in either one of the first and second multi-level buffers MLB1 and MLB2 of the respective first and second memory device 1501 and 1502 without leaving any empty space.

However, the controller 130 may be able to move all the data, buffered in the second multi-level buffer MLB2 of the second memory device 1502, to the first multi-level buffer MLB1 of the first memory device 1501 as in FIG. 13 because the input data DATA<0:3> has a size that is smaller than the preset size. Accordingly, the controller 130 may move the data, buffered in the second lower level buffers LSB21 and LSB22 of the second memory device 1502, that is, the second and the third data DATA<2:3>, to the first middle level buffers CSB11 and CSB12 of the first memory device 1501.

However, even after the second and the third data DATA<2:3> buffered in the second lower level buffers LSB21 and LSB22 of the second memory device 1502 have been moved to the first middle level buffers CSB11 and CSB12 of the first memory device 1501, the first higher level buffers MSB11 and MSB12 of the first memory device 1501 may be empty spaces.

Accordingly, the controller 130 may still need to buffer dummy data DUMMY in the empty spaces of the first multi-level buffer MLB1 of the first memory device 1501 before performing the one-shot program operation on the first memory device 1501. For example, the controller 130 may buffer the dummy data DUMMY in the first higher level buffers MSB11 and MSB12 of the first multi-level buffer MLB1 of the first memory device 1501 and then perform the one-shot program operation on the first memory device 1501.

In FIG. 13G, it is assumed that input data DATA<0:1> may have a size that is smaller than the preset size”, unlike in the case of FIG. 13A where the input data DATA<0:5> have a size equal to the preset size. For example, in FIG. 13G, a total number of the input data DATA<0:1> may be 2 and the input data DATA<0:1> may have the size smaller than the “preset size.” Accordingly, it may be considered that all of the input data DATA<0:1> have been buffered at the time of completion of buffering the input data DATA<0:1> in the first lower level buffers LSB11 and LSB12 only.

In this case, it may be considered that all of the input data DATA<0:1> have been buffered if they have been buffered only in the first lower level buffers LSB11 and LSB12 of the first memory device 1501. Accordingly, the input data DATA<0:1> may not be buffered in the second lower level buffers LSB21 and LSB22 of the second memory device 1502, the first middle level buffers CSB11 and CSB12 of the first memory device 1501, the second middle level buffers CSB21 and CSB22 of the second memory device 1502, the first higher level buffers MSB11 and MSB12 of the first memory device 1501, and the second higher level buffers MSB21 and MSB22 of the second memory device 1502.

In this case, the one-shot program operation does not need to be performed on the second memory device 1502 because the second multi-level buffer MLB2 of the second memory device 1502 remains fully empty.

In contrast, the input data DATA<0:1> have been buffered only in the first lower level buffers LSB11 and LSB12 of the first multi-level buffer MLB1 of the first memory device 1501. Accordingly, dummy data DUMMY may need to be buffered in the first middle level buffers CSB11 and CSB12 and the first higher level buffers MSB11 and MSB12 before the one-shot program operation may be performed on the first memory device 1501. For example the controller 130 may buffer the dummy data DUMMY in the first middle level buffers CSB11 and CSB12 and first higher level buffers MSB11 and MSB12 of the first multi-level buffer MLB1 of the first memory device 501 and then perform the one-shot program operation on the first memory device 1501.

According to embodiments of the invention, a memory system is provided including a plurality of memory devices, wherein the number of memory devices on which a one-shot program is actually performed may be adjusted based on the size of input data and a preset data size.

Accordingly, the present invention memory system may be advantageous over existing systems in that a one-shot program may be performed in an optimum data form based on the size of input data in a plurality of memory devices.

Although various embodiments have been described for illustrative purposes, it will be apparent to those skilled in the art that various changes and modifications may be made without departing from the spirit and or scope of the invention as defined in the following claims.

What is claimed is:

1. A memory system, comprising:
a first memory device comprising a first mu ti-level cell and a first multi-level buffer;
a second memory device comprising a second multi-level cell and a second multi-level buffer; and
a controller suitable for buffering input data in the first and the second multi-level buffers in an interleaving way, for rearranging and storing the buffered input data in a multi-level buffer selected from the first and second multi-level buffers if the input data have a size smaller than or equal to a preset size, wherein a one-shot program is performed on a memory device including the selected multi-level buffer.

2. The memory system of claim 1, wherein the controller performs the one-shot program on each of the first and the second memory devices so that the data buffered in the first and the second multi-level buffers can be programmed into the first and the second memory devices if the input data have a size greater than the preset size.

3. The memory system of claim 2, wherein the preset size comprises a size of the input data corresponding to a size required for buffering the input data in each of the first and the second multi-level buffers at unit level.

4. The memory system of claim 3, wherein each of the first and the second multi-level buffers comprises a plurality of lower level buffers and a plurality of higher level buffers, and if all of the input data have been buffered at the time of sequentially buffering the input data in the lower level buffers of the first and the second multi-level buffers, the controller moves the data buffered in the lower level buffers of the second multi-level buffer to the higher level buffers of the first multi-level buffer to perform the one-shot program on the first memory device.

5. The memory system of claim 4, wherein if all of the input data have not been buffered at the time of completion of sequentially buffering the input data in the lower level buffers of the first and the second multi-level buffers, the controller sequentially buffers the input data in the higher level buffers of the first and the second multi-level buffers based on the size of the input data which have not been buffered or buffers the input data in the higher level buffers of the first multi-level buffer and buffers dummy data in the higher level buffers of the second multi-level buffer, to perform the one-shot program on each of the first and the second memory devices.

6. The memory system of claim 5, wherein if all of the input data have been buffered at the time of buffering the input data in the lower level buffers of the first multi-level buffer, the controller buffers the dummy data in the higher level buffers of the first multi-level buffer to perform the one-shot program on the first memory device.

7. The memory system of claim 2, wherein the preset size comprises a size of the input data corresponding to a half of a sum of sizes of the first and the second multi-level buffers.

8. The memory system of claim 7, wherein each of the first and second multi-level buffers comprises a plurality of lower level buffers, a plurality of middle level buffers and a plurality of higher level buffers, and if all of the input data have been buffered at the time of completion of sequentially buffering the input data in the lower level buffers of the first and the second multi-level buffers and the middle level buffers of the first multi-level buffer, the controller moves data buffered in the middle level buffers of the first multi-level buffer to the higher level buffers of the first multi-level buffer and moves data buffered in the lower level buffers of the second multi-level buffer to the middle level buffers of the first multi-level buffer, to performs the one-shot program on the first memory device.

9. The memory system of claim 8, wherein if all of the input data have not been buffered at the time of completion of sequentially buffering the input data in the lower level buffers of the first and the second multi-level buffers and the middle level buffers of the first multi-level buffer, the controller sequentially buffers the input data in the middle level buffers of the second multi-level buffer and the higher level buffers of the first and the second multi-level buffers based on a size of the input data which have not been buffered or sequentially buffers the input data in the middle level buffers of the second multi-level buffer and the higher level buffers of the first multi-level buffer, buffers dummy data in the higher level buffers of the second multi-level buffer or buffers the input data in the middle level buffers of the second multi-level buffer and buffers dummy data in the higher level buffers of the first and the second multi-level buffers to perform the one-shot program on each of the first and the second memory devices.

10. The memory system of claim 9, wherein if all of the input data have been buffered at the time of completion sequentially buffering the input data in the lower level buffers of the first and the second multi-level buffers, the controller moves data buffered in the lower level buffers of the second multi-level buffer to the middle level buffers of the first multi-level buffer and buffers dummy data in the higher level buffers of the first multi-level buffer to perform the one-shot program on the first memory device.

11. The memory system of claim 10, wherein if all of the input data have been buffered at the time of completion of buffering the input data in the lower level buffers of the first multi-level buffer, the controller buffers the dummy data in the middle level buffers and the higher level buffers of the first multi-level buffer to perform the one-shot program on the first memory device.

12. An operating method of a memory system comprising a first memory device comprising a first multi-level cell and a first multi-level buffer and a second memory device comprising a second multi-level cell and a second multi-level buffer, the operating method comprising:
a step of buffering input data in the first and the second multi-level buffers in an interleaving way and checking a size of the input data based on a preset size;
a first program step of storing the buffered input data in a multi-level buffer selected from the first and the second multi-level buffers if, as a result of the checking, the input data have a size smaller than or equal to the preset size and performing a one-shot program on a memory device including the selected multi-level buffer; and
a second program step of performing the one-shot program on each of the first and the second memory devices so that the data buffered in the first and the second multi-level buffers can be programmed into the first and the second memory devices if, as a result of the checking, the input data have a size greater than the preset size.

13. The operating method of claim 12, wherein the preset size comprises a size of the input data corresponding to a size required for buffering the input data in each of the first and the second multi-level buffers at unit level.

14. The operating method of claim 13, wherein each of the first and the second multi-level buffers comprises a plurality of lower level buffers and a plurality of higher level buffers, and if, as a result of the checking, the input data having the preset size are found to have been sequentially buffered in the lower level buffers of the first and the second multi-level buffers, the first program step comprises:
moving data buffered in the lower level buffers of the second multi-level buffer to the higher level buffers of the first multi-level buffer, and
performing the one-shot program on the first memory device.

15. The operating method of claim 14, wherein if, as a result of the checking, the input data having the size smaller than the preset size are found to have been buffered in the lower level buffers of the first multi-level buffer, the first program step comprises:
buffering dummy data in the higher level buffers of the first multi-level buffer, and
performing the one-shot program on the first memory device.

16. The operating method of claim 15, wherein the second program step comprises:
performing the one-shot program on each of the first and the second memory devices if, as a result of the checking, the input data having the size greater than the preset size are found to have been sequentially buffered in the lower level buffers and the higher level buffers of the first and the second multi-level buffers; and
buffering the dummy data in the higher level buffers of the second multi-level buffer and performing the one-shot program on each of the first and the second memory devices if, as a result of the checking, the input data having the size greater than the preset size are found to have been sequentially buffered in the lower level buffers of the first and the second multi-level buffers and the higher level buffers of the first multi-level buffer.

17. The operating method of claim 12 wherein the preset size comprises a size of the input data corresponding to a half of a sum of sizes of the first and the second multi-level buffers.

18. The operating method of claim 17, wherein each of the first and second multi-level buffers comprises a plurality of lower level buffers, a plurality of middle level buffers and a plurality of higher level buffers, and if, as a result of the checking, the input data having the preset size are found to have been sequentially buffered in the lower level buffers of the first and the second multi-level buffers and the middle level buffers of the first multi-level buffer, the first program step comprises:
moving data buffered in the middle level buffers of the first multi-level buffer to the higher level buffers of the first multi-level buffer,
moving data buffered in the lower level buffers of the second multi-level buffer to the middle level buffers of the first multi-level buffer, and
performing the one-shot program on the first memory device.

19. The operating method of claim 18, wherein the first program step comprises:
moving data buffered in the lower level buffers of the second multi-level buffer to the middle level buffers of the first multi-level buffer, buffering dummy data in the higher level buffers of the first multi-level buffer, and performing the one-shot program on the first memory device if, as a result of the checking, the input data having the size smaller than the preset size are found to have been sequentially buffered in the lower level buffers of the first and the second multi-level buffers; and
buffering dummy data in the middle level buffers and the higher level buffers of the first multi-level buffer and performing the one-shot program on the first memory device if, as a result of the checking, the input data having the size smaller than the preset size are found to have been buffered in the lower level buffers of the multi-level buffer,

20. The operating method of claim 19, wherein the second program step comprises:
performing the one-shot program on each of the first and the second memory devices if, as a result of the checking, the input data having the size greater than the preset size are found to have been sequentially buffered in the lower level buffers, the middle level buffers, and the higher level buffers of the first and the second multi-level buffers;
buffering the dummy data in the higher level buffers of the second multi-level buffer and performing the one-shot program on each of the first and the second memory devices if, as a result of the checking, the input data having the size greater than the preset size are found to have been sequentially buffered in the lower level buffers and the middle level buffers of the first and the second multi-level buffers and the higher level buffers of the first multi-level buffer; and
buffering the dummy data in the higher level buffers of the first and the second multi-level buffers and performing the one-shot program on the first and the second memory devices if as a result of the checking, the input data having the size greater than the preset size are found to have been sequentially buffered in the lower level buffers and the middle level buffers of the first and the second multi-level buffers.
